(19) United States
(12) Patent Application Publication
(10) Pub. No.: US 2025/0277969 A1
(43) Pub. Date: Sep. 4, 2025

(54) OPTICAL REFLECTION ELEMENT AND METHOD FOR MANUFACTURING OPTICAL REFLECTION ELEMENT

(71) Applicant: Panasonic Intellectual Property Management Co., Ltd., Osaka (JP)

(72) Inventor: Takami ISHIDA, Osaka (JP)

(21) Appl. No.: 19/213,067

(22) Filed: May 20, 2025

Related U.S. Application Data
(63) Continuation of application No. PCT/JP2023/040876, filed on Nov. 14, 2023.

(30) Foreign Application Priority Data
Nov. 28, 2022 (JP) 2022-189566

(51) Int. Cl. G02B 26/08; H10N 30/06; H10N 30/082; H10N 30/20

(52) U.S. Cl. CPC G02B 26/0858; H10N 30/06; H10N 30/082; H10N 30/2043; H10N 30/2044

(57) ABSTRACT

An optical reflection element includes a movable part and a drive part configured to rotate the movable part about a rotation axis. At least a layer structure that is the same as in a range from a piezoelectric layer to an upper surface of a substrate in a region of the drive part is placed in a region of an outer peripheral portion of the movable part on the substrate. A layer structure that is the same as in a range from a lower electrode layer to the upper surface of the substrate in the region of the drive part is placed in a region of a center portion of the movable part on the substrate. An upper surface of the lower electrode layer in the region of the center portion is exposed to outside to constitute a reflection surface.

### CROSS REFERENCE TO RELATED APPLICATION

This application is a continuation of International Application No. PCT/JP2023/040876 filed on Nov. 14, 2023, entitled “OPTICAL REFLECTION ELEMENT AND METHOD FOR MANUFACTURING OPTICAL REFLECTION ELEMENT”, which claims priority under 35 U.S.C. Section 119 of Japanese Patent Application No. 2022-189566 filed on Nov. 28, 2022, entitled “OPTICAL REFLECTION ELEMENT AND METHOD FOR MANUFACTURING OPTICAL REFLECTION ELEMENT”. The disclosures of the above applications are incorporated herein by reference.

### BACKGROUND OF THE INVENTION

### FIELD OF THE INVENTION

The present invention relates to an optical reflection element that drives a movable part having a reflection surface formed thereon, and a method for manipulating the optical reflection element.

### DESCRIPTION OF RELATED ART

An optical reflection element that drives a movable part having a reflection surface formed thereon, has been known. In this type of optical reflection element, for example, a reflection surface is positioned on a movable part that rotates about a rotation axis, and scanning is performed with a beam incident on the reflection surface as the movable part rotates.

Japanese Laid-Open Patent Publication No. 2019-82625 describes an optical reflection element that includes: a reflection body that rotates and oscillates around a rotation axis and is for reflecting light; a connection body that is placed along the rotation axis and coupled to the reflection body; and a drive body that rotates and oscillates the connection body. The reflection body, the connection body, and the drive body are formed by removing unnecessary portions of a silicon substrate. A reflection part that reflects light is placed on the surface of the reflection body. An electrode and a piezoelectric body are stacked on the surface of the drive body.

In the above-described optical reflection element, it is preferable to be able to easily and stably position a reflection surface whose warpage is suppressed and that has a high reflectance.

### SUMMARY OF THE INVENTION

An optical reflection element according to a first aspect of the present invention includes: a movable part; and a drive part configured to rotate the movable part about a rotation axis. A lower electrode layer, an upper electrode layer located above the lower electrode layer, and a piezoelectric layer located between the lower electrode layer and the upper electrode layer are placed in a region of the drive part on a substrate that forms an outer shell of the optical reflection element. At least a layer structure that is the same as in a range from the piezoelectric layer to an upper surface of the substrate in the region of the drive part is placed in a region of an outer peripheral portion of the movable part on the substrate. A layer structure that is the same as in a range from the lower electrode layer to the upper surface of the substrate in the region of the drive part is placed in a region of a center portion of the movable part on the substrate. An upper surface of the lower electrode layer in the region of the center portion is exposed to outside to constitute a reflection surface.

In the optical reflection element according to this aspect, since the lower electrode layer is used as the reflection surface, the reflection surface having a high reflectance can be easily formed. In addition, in the region of the outer peripheral portion of the movable part, the layer structure that is the same as in the range from the piezoelectric layer to the upper surface of the substrate is placed and made thicker, so that warpage of the reflection surface inside this layer structure is suppressed by this layer structure. Here, the layer structure is placed on the upper surface of the movable part as with the reflection surface and is adjacent to the reflection surface, so that warpage of the reflection surface is effectively suppressed by the layer structure. Therefore, the reflection surface whose warpage is effectively suppressed can be stably positioned. Therefore, in the optical reflection element according to this aspect, the reflection surface that has a high reflectance and whose warpage is suppressed can be easily and stably positioned.

A method for manufacturing an optical reflection element according to a second aspect of the present invention includes the steps of: forming a lower electrode layer, a piezoelectric layer, and an upper electrode layer in this order from a substrate side; removing the upper electrode layer such that the upper electrode layer is left at least in a range of a drive part; removing the lower electrode layer and the piezoelectric layer such that the lower electrode layer and the piezoelectric layer are left at least in the range of the drive part and a range of a movable part; removing the piezoelectric layer from the movable part such that the piezoelectric layer is left in an outer peripheral portion of the movable part to expose an upper surface of the lower electrode layer; and removing the substrate in a range other than the optical reflection element.

With the method for manufacturing the optical reflection element according to this aspect, after the layer structure including the lower electrode layer, the piezoelectric layer, and the upper electrode layer is formed on the substrate, each layer of the layer structure is selectively removed by etching, whereby the movable part and the drive part can be formed together in the same process. Accordingly, device creation can be achieved at low cost. In this formation process, wet etching is applied to the region of the center portion of the movable part to expose the lower electrode layer to the outside, whereby formation of unevenness in the upper surface of the lower electrode layer due to etching can be suppressed, and a reduction in the reflectance of the upper surface can be suppressed. In addition, during this wet etching, at least the layer structure from the piezoelectric layer to the substrate is left in the region of the outer peripheral portion of the movable part, so that a resist is placed on the upper side and the outer side of the outer peripheral portion. Therefore, the wet etching etchant does not enter the boundary between the substrate and the lower electrode layer from the outside, and occurrence of peeling in the outer peripheral portion of the lower electrode layer can be suppressed. Therefore, the reflection surface whose reflectance is inhibited from being reduced can be easily and stably positioned on the movable part.

The effects and the significance of the present invention will be further clarified by the description of the embodiments below. However, the embodiments below are merely examples for implementing the present invention. The present invention is not limited to the description of the embodiments below in any way.

### BRIEF DESCRIPTION OF THE DRAWINGS

FIG. 1 is a plan view schematically showing a configuration of an optical reflection element according to Embodiment 1;

FIG. 2A and FIG. 2B are respectively a plan view and a cross-sectional view schematically showing a configuration of a movable part according to Embodiment 1;

FIG. 3 shows a plan view and cross-sectional views for describing a procedure for forming the optical reflection element according to Embodiment 1;

FIG. 4 shows a plan view and cross-sectional views for describing the procedure for forming the optical reflection element according to Embodiment 1;

FIG. 5 shows a plan view and cross-sectional views for describing the procedure for forming the optical reflection element according to Embodiment 1;

FIG. 6 shows a plan view and cross-sectional views for describing the procedure for forming the optical reflection element according to Embodiment 1;

FIG. 7 shows a plan view and cross-sectional views for describing the procedure for forming the optical reflection element according to Embodiment 1;

FIG. 8 shows a plan view and cross-sectional views for describing the procedure for forming the optical reflection element according to Embodiment 1;

FIG. 9 shows a plan view and cross-sectional views for describing the procedure for forming the optical reflection element according to Embodiment 1;

FIG. 10 a diagram illustrating a problem that occurs when dry etching is performed, according to a comparative example;

FIG. 11A is a cross-sectional view for illustrating that a lower electrode peels off when a resist is placed so as to match a range of the lower electrode, according to the comparative example;

FIG. 11B is a cross-sectional view for illustrating that peeling of a lower electrode is suppressed when a resist is placed so as to cover an outer peripheral portion of the lower electrode, according to Embodiment 1;

FIG. 12 shows a plan view and cross-sectional views for describing the procedure for forming the optical reflection element according to Embodiment 1;

FIG. 13 shows a plan view and cross-sectional views for describing the procedure for forming the optical reflection element according to Embodiment 1;

FIG. 14 shows a plan view and cross-sectional views for describing the procedure for forming the optical reflection element according to Embodiment 1;

FIG. 15 shows a plan view and cross-sectional views for describing the procedure for forming the optical reflection element according to Embodiment 1;

FIG. 16 is a flowchart showing the procedure for forming the optical reflection element according to Embodiment 1;

FIG. 17A and FIG. 17B are respectively a plan view and a cross-sectional view schematically showing a configuration of a movable part according to Modification 1 of Embodiment 1;

FIG. 18A to FIG. 18C are cross-sectional views for describing a procedure for forming an optical reflection element according to Modification 1 of Embodiment 1;

FIG. 19A and FIG. 19B are respectively a plan view and a cross-sectional view schematically showing a configuration of a movable part according to Modification 2 of Embodiment 1;

FIG. 20A and FIG. 20B are respectively a plan view and a cross-sectional view schematically showing a configuration of a movable part according to Modification 3 of Embodiment 1; and

FIG. 21 is a plan view schematically showing a configuration of an optical reflection element according to Embodiment 2.

It should be noted that the drawings are solely for description and do not limit the scope of the present invention by any degree.

### DETAILED DESCRIPTION

Hereinafter, embodiments of the present invention will be described with reference to the drawings. For convenience, in each drawing, X, Y, and Z axes that are orthogonal to each other are additionally shown. The Z-axis positive direction is the vertical upward direction.

### Embodiment 1

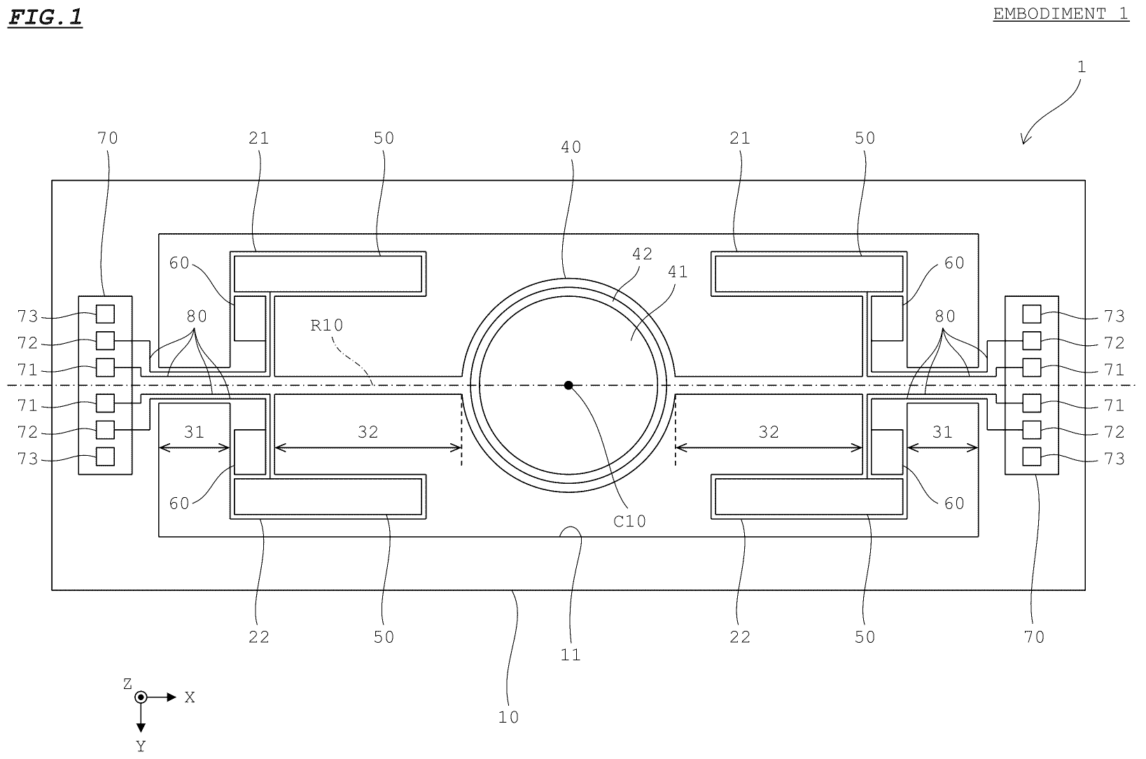

FIG. 1 is a plan view schematically showing a configuration of an optical reflection element 1.

The optical reflection element 1 includes a fixation part 10, a pair of vibration parts 21, a pair of vibration parts 22, a pair of connection parts 31, a pair of connection parts 32, a movable part 40, four drive parts 50, four detection parts 60, eight wires 80, and a pair of electrode parts 70. The optical reflection element 1 is configured to be symmetrical in the X-axis direction and the Y-axis direction about a center C10 thereof.

The fixation part 10 is configured in a frame shape. The movable part 40 has a circular shape in a plan view. The movable part 40 is supported by the fixation part 10 via the pairs of vibration parts 21 and 22. The movable part 40 is placed at the position of the center C10 of the optical reflection element 1 and rotates about a rotation axis R10 that passes through the center C10 and extends in the X-axis direction. The movable part 40 has a shape that is symmetrical about the rotation axis R10 in a plan view.

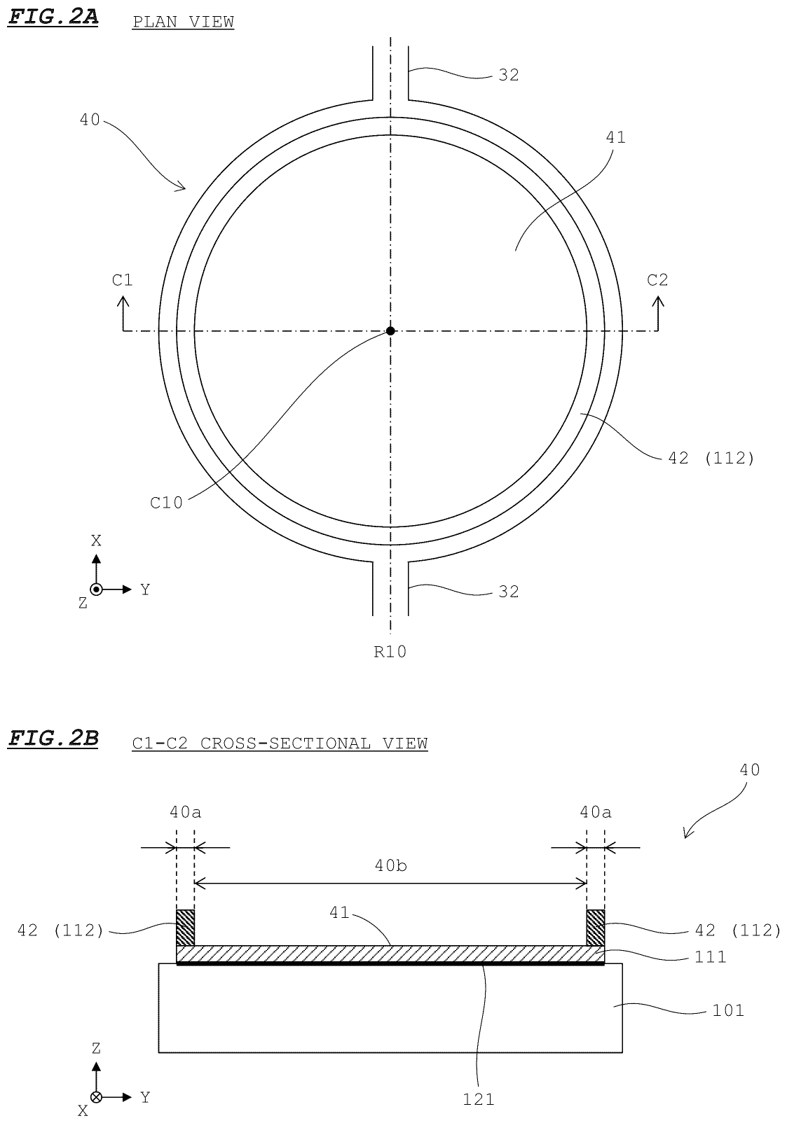

A reflection surface 41 that reflects light is formed at the center of the movable part 40, and a protrusion 42 that protrudes in the Z-axis positive direction with respect to the reflection surface 41 is formed at the outer periphery of the movable part 40. A layer structure of the movable part 40 will be described later with reference to FIG. 2A and FIG. 2B.

The pairs of vibration parts 21 and 22 and the pairs of connection parts 31 and 32 are placed in an opening 11 that penetrates the fixation part 10 in the Z-axis direction at the center of the fixation part 10 in a plan view, and end portions of the connection parts 31 are supported by the fixation part 10.

The vibration parts 21 and 22 each have an L-shape in a plan view. The vibration parts 21 and 22 each have a shape that extends in the X-axis direction, in the vicinity of a distal end thereof, and each have a shape that extends in the Y-axis direction, in the vicinity of the connection to the connection parts 31 and 32. In the vicinity of the rotation axis R10, the vibration parts 21 and 22 are connected to the fixation part 10 via the connection parts 31 and are connected to the movable part 40 via the connection parts 32. The vibration parts 21 are placed on the Y-axis negative side of the rotation axis R10, and the vibration parts 22 are placed on the Y-axis positive side of the rotation axis R10. The connection parts 31 and 32 extend in the X-axis direction along the rotation axis R10. The vibration parts 21 and 22 located on the X-axis positive side or the X-axis negative side of the movable part 40 have a tuning fork shape in a plan view.

The drive parts 50 and the detection parts 60 are placed on the upper surfaces of the vibration parts 21 and 22. The electrode parts 70 are placed on the upper surface of the fixation part 10. One electrode part 70 includes two first electrode portions 71, two second electrode portions 72, and two third electrode portions 73. The number of third electrode portions 73 placed in one electrode part 70 may be one or three or more. Cables (external wires) connected to an external device are connected to the upper surfaces of the first electrode portions 71, the second electrode portions 72, and the third electrode portions 73 by wire bonding.

The drive parts 50, the detection parts 60, the wires 80, the first electrode portions 71, and the second electrode portions 72 each have a layer structure including a lower electrode layer 111, a piezoelectric layer 112, and an upper electrode layer 113 which will be described later. The region of each electrode part 70 other than the first electrode portions 71, the second electrode portions 72, and the third electrode portions 73 has a layer structure including a lower electrode layer 111 and a piezoelectric layer 112. Each third electrode portion 73 has a lower electrode layer 111.

The upper electrode layers 113 of the drive parts 50 and the detection parts 60 are connected to the upper electrode layers 113 of the first electrode portions 71 and the second electrode portions 72 via the upper electrode layers 113 of the wires 80, respectively. The first electrode portions 71 are connected to a power supply, a power supply circuit, or the like in the external device, and the second electrode portions 72 are connected to an ammeter, a current detection circuit, or the like in the external device. The lower electrode layers 111 of the drive parts 50 and the detection parts 60 are connected to the lower electrode layers 111 of the third electrode portions 73 via the lower electrode layers 111 of the wires 80. The third electrode portions 73 are connected to a ground in the external device.

When drive voltages are applied to the drive parts 50 via the first electrode portions 71, the piezoelectric layers 112 in the drive parts 50 become deformed due to an inverse piezoelectric effect, so that the vibration parts 21 and 22 on which the drive parts 50 are installed vibrate so as to bend. When the optical reflection element 1 is driven, drive voltages having opposite phases are applied to the drive parts 50 on the vibration parts 21 and the drive parts 50 on the vibration parts 22, and drive voltages having the same phase are applied to the drive parts 50 on the pair of vibration parts 21. Accordingly, the movable part 40 rotates about the rotation axis R10, and the direction of light that is incident on the reflection surface 41 is changed in accordance with the rotation angle of the movable part 40.

Meanwhile, when bending occurs in the vibration parts 21 and 22, the detection parts 60 placed on the vibration parts 21 and 22 become deformed. At this time, a current flows from the detection parts 60 to the second electrode portions 72 via the wires 80 due to a piezoelectric effect. Therefore, bending of the vibration parts 21 and 22 can be detected based on a current value detected by the external device connected to the second electrode portions 72.

FIG. 2A and FIG. 2B are respectively a plan view and a cross-sectional view schematically showing a configuration of the movable part 40. FIG. 2B is a cross-sectional view of a C1-C2 cross-section in the plan view of FIG. 2A as seen in the X-axis positive direction.

The movable part 40 has a layer structure including a substrate 101, a lower electrode layer 111, and a piezoelectric layer 112. An adhesion layer 121 is placed between the substrate 101 and the lower electrode layer 111 in order to enhance the adhesion between the substrate 101 and the lower electrode layer 111. In the movable part 40, the substrate 101 and the lower electrode layer 111 each have a circular shape in a plan view, and the diameter of the lower electrode layer 111 is slightly smaller than the diameter of the substrate 101.

A layer structure composed of the adhesion layer 121, the lower electrode layer 111, and the piezoelectric layer 112 is placed in the region of an outer peripheral portion 40a of the movable part 40 on the substrate 101. A layer structure composed of the adhesion layer 121 and the lower electrode layer 111 is placed in the region of a center portion 40b of the movable part 40 on the substrate 101. The piezoelectric layer 112 of the movable part 40 is formed in a ring shape in a plan view along an outer peripheral portion of the lower electrode layer 111 on the upper surface of the lower electrode layer 111.

In the region of the center portion 40b, the upper surface of the lower electrode layer 111 is exposed to the outside and forms the reflection surface 41. In the region of the outer peripheral portion 40a, the piezoelectric layer 112 protrudes from the upper surface of the lower electrode layer 111 and forms the protrusion 42.

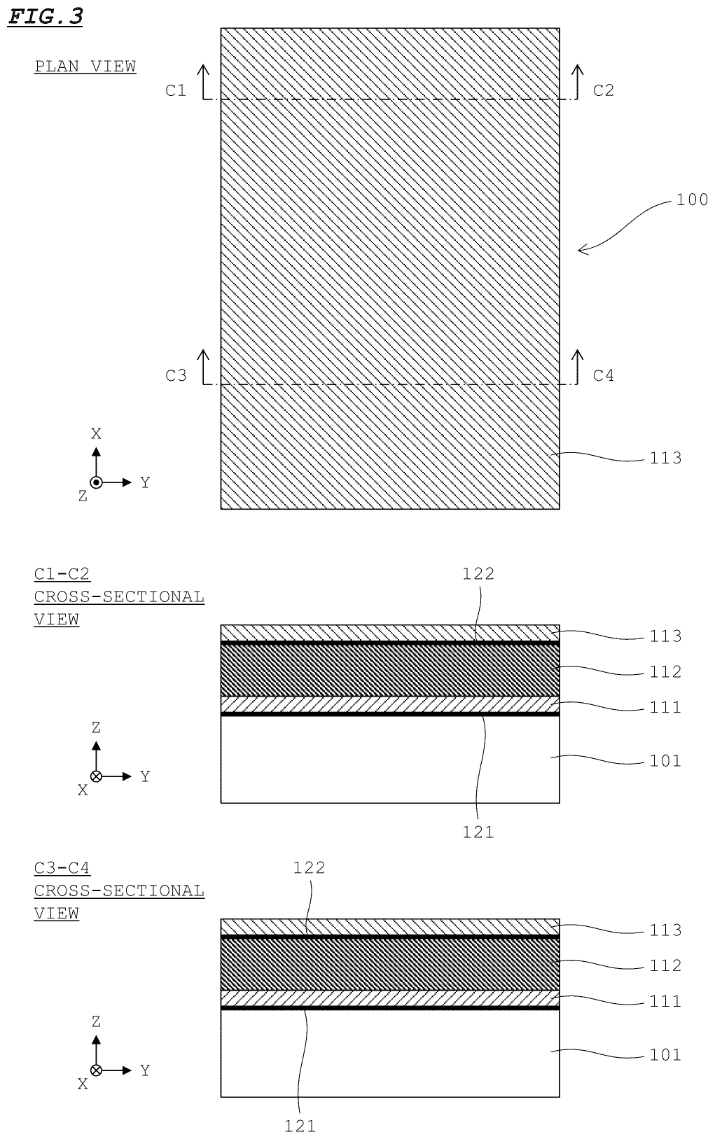

Next, a procedure for forming the optical reflection element 1 will be described with reference to plan views and cross-sectional views in FIG. 3 to FIG. 15.

FIG. 3 to FIG. 9 and FIG. 12 to FIG. 15 schematically show a configuration of a region located around the X-axis negative side and the Y-axis negative side of the center C10. Hereinafter, for convenience, the formation procedure for this region will be described.

The drawings shown in the upper parts of FIG. 3 to FIG. 9 and FIG. 12 to FIG. 15 are each a plan view of the optical reflection element 1 and a configuration in the middle of formation. The drawings shown in the middle parts of FIG. 3 to FIG. 9 and FIG. 12 to FIG. 15 are views of C1-C2 cross-sections in the plan views shown in the upper parts of FIG. 3 to FIG. 9 and FIG. 12 to FIG. 15 as seen in the X-axis positive direction, respectively. The drawings shown in the lower parts of FIG. 3 to FIG. 9 and FIG. 12 to FIG. 15 are views of C3-C4 cross-sections in the plan views shown in the upper parts of FIG. 3 to FIG. 9 and FIG. 12 to FIG. 15 as seen in the X-axis positive direction, respectively. In addition, in FIG. 3 to FIG. 9 and FIG. 12 to FIG. 15, in the plan views in the upper parts, the same materials as in the cross-sectional views in the middle and lower parts are shown by the same oblique lines.

In the drawings described below, for convenience of description, an end portion of the drive part 50 and the third electrode portion 73 are shown on the C3-C4 cross-section. In addition, the detection parts 60, the wires 80, the first electrode portions 71, and the second electrode portions 72 have the same configuration as the drive parts 50, and thus are not shown for convenience.

As shown in FIG. 3, a non-processed substrate 100 in which the substrate 101, the adhesion layer 121, the lower electrode layer 111, the piezoelectric layer 112, an adhesion layer 122, and the upper electrode layer 113 are stacked in this order, is prepared.

The substrate 101 is made of silicon (Si), for example. A thermal oxide film made of silicon dioxide (Si02), for example, is formed on the upper surface of the substrate 101 by thermal oxidation treatment. The adhesion layer 121 is placed in order to enhance the adhesion between the substrate 101 and the lower electrode layer 111 and is made of titanium (Ti), for example. The lower electrode layer 111 is made platinum (Pt), for example. The piezoelectric layer 112 is composed of a single crystal structure of PZT (lead zirconate titanate: Pb(Zr, Ti)O₃). The adhesion layer 122 is placed in order to enhance the adhesion between the piezoelectric layer 112 and the upper electrode layer 113 and is made of the same material as the adhesion layer 121. The upper electrode layer 113 is made of gold (Au), for example.

The upper surface of the substrate 101 is thermally oxidized, and the adhesion layer 121, the lower electrode layer 111, the piezoelectric layer 112, the adhesion layer 122, and the upper electrode layer 113 are stacked in this order on the substrate 101 by a PVD method such as sputtering and vapor deposition, a sol-gel method, a CVD method, or the like to form the non-processed substrate 100.

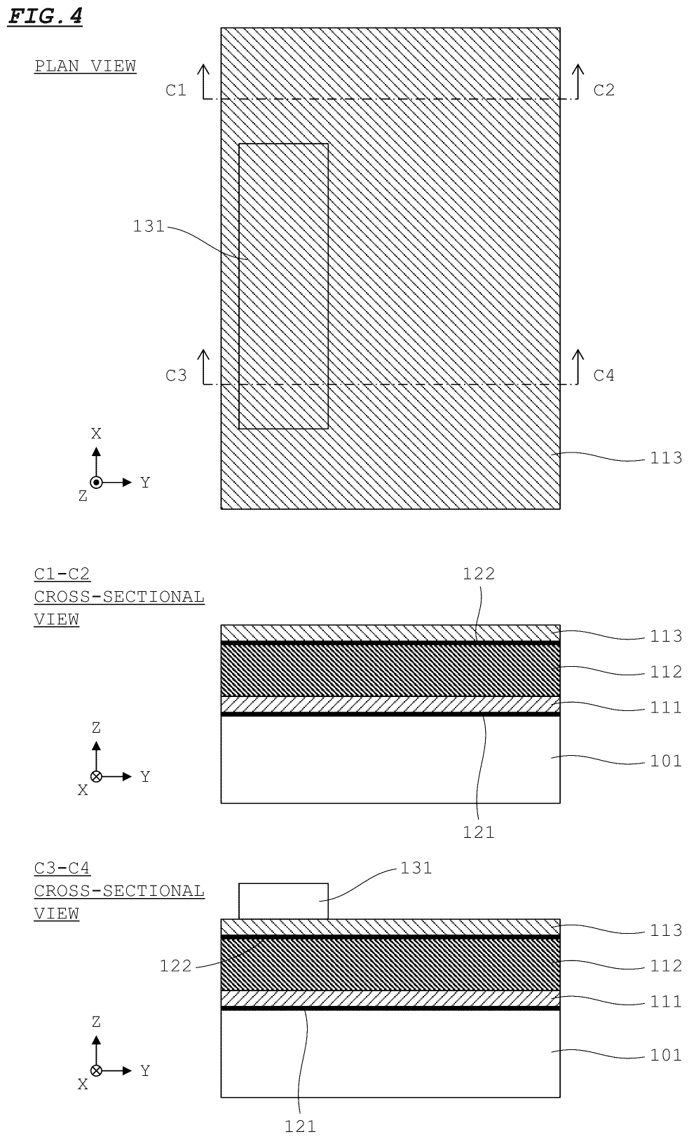

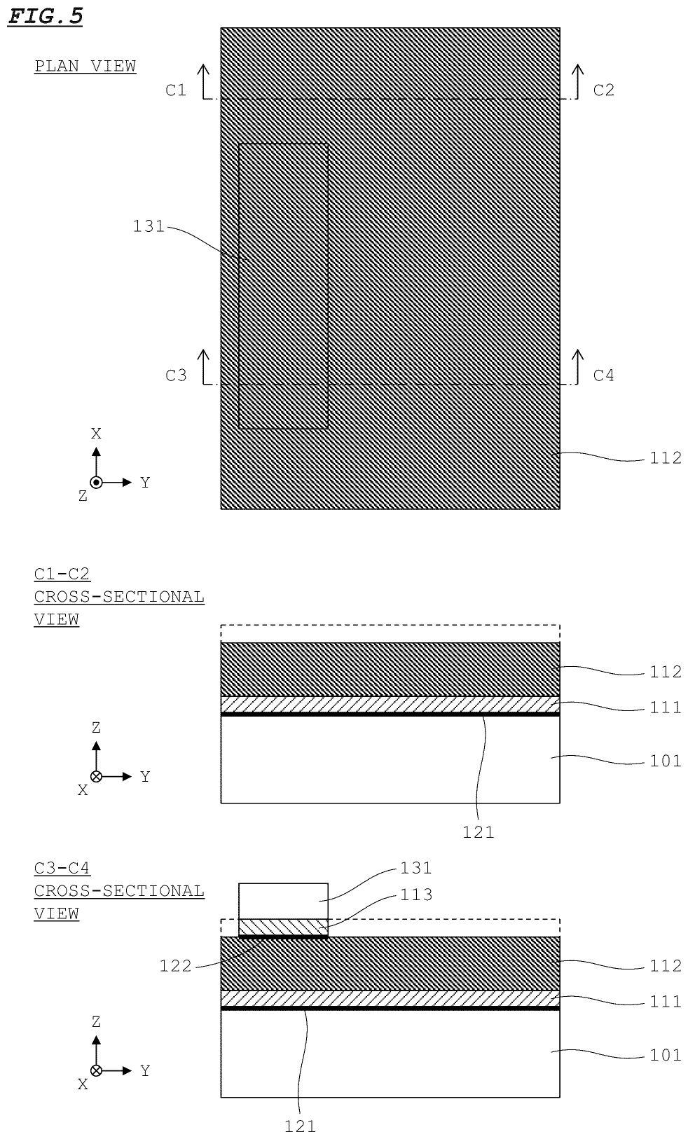

Subsequently, as shown in FIG. 4, a resist 131 is placed in a region where the upper electrode layer 113 is to be left. The region where the upper electrode layer 113 is to be left is specifically the ranges of the drive parts 50, the detection parts 60, the wires 80, the first electrode portions 71, and the second electrode portions 72 shown in the plan view of FIG. 1. Then, dry etching is performed on the configuration in FIG. 4 from above. Accordingly, as shown in FIG. 5, the upper electrode layer 113 and the adhesion layer 122 are removed in the region other than the resist 131, and the resist 131 is then removed.

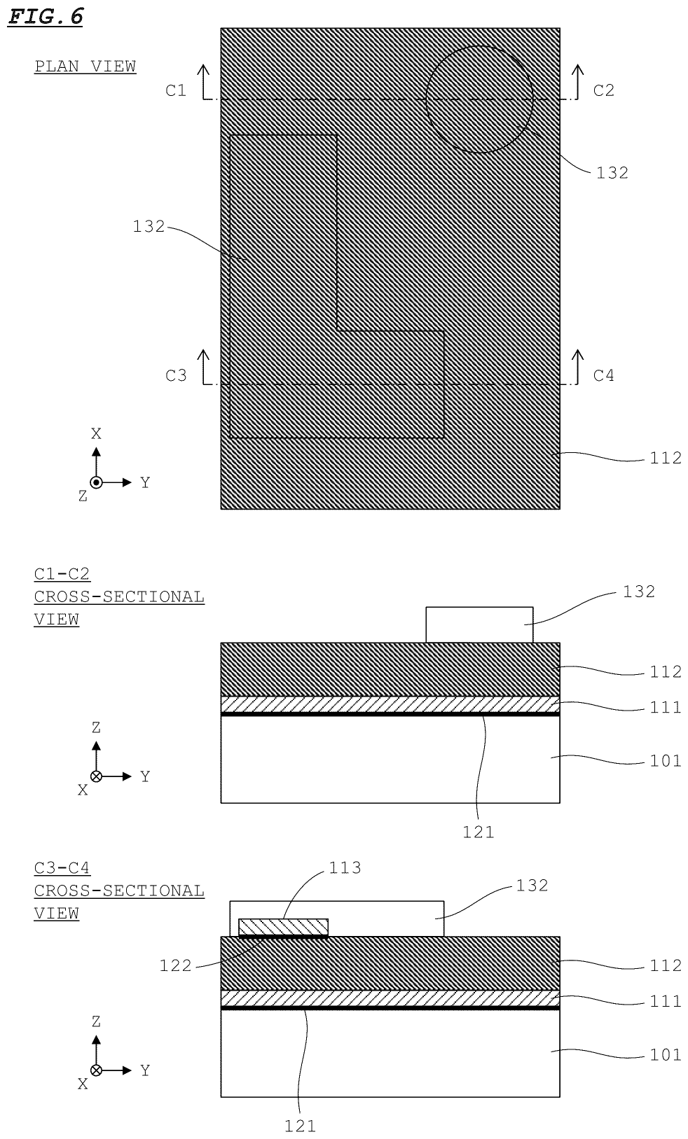

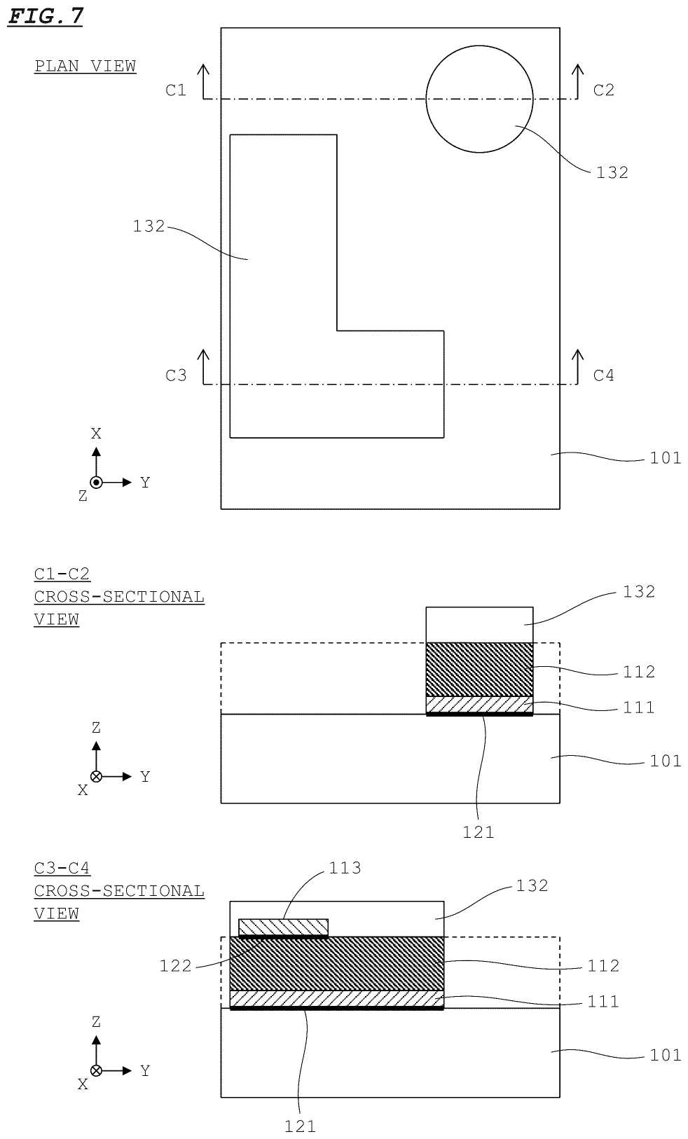

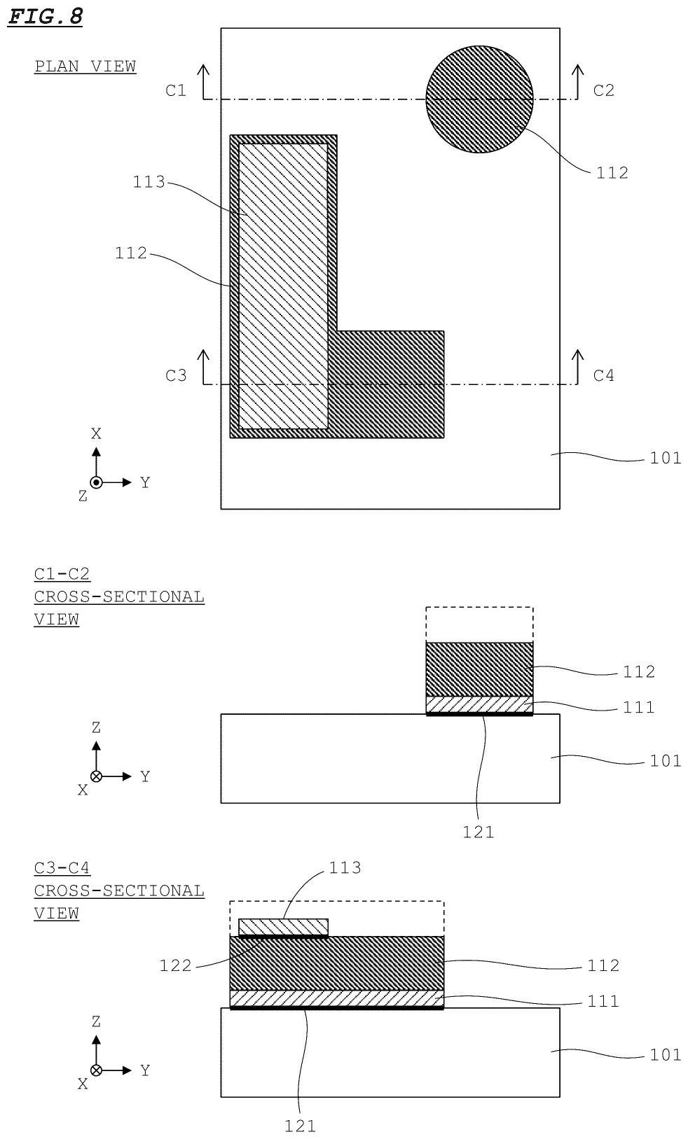

Subsequently, as shown in FIG. 6, a resist 132 is placed in a region where the lower electrode layer 111 and the piezoelectric layer 112 are to be left. The region where the lower electrode layer 111 and the piezoelectric layer 112 are to be left is specifically the ranges of the movable part 40, the drive parts 50, the detection parts 60, the wires 80, and the electrode parts 70 shown in the plan view of FIG. 1. Then, dry etching is performed on the configuration in FIG. 6 from above. Accordingly, as shown in FIG. 7, the lower electrode layer 111, the piezoelectric layer 112, and the adhesion layer 121 are removed in the region other than the resist 132, and the resist 132 is removed as shown in FIG. 8.

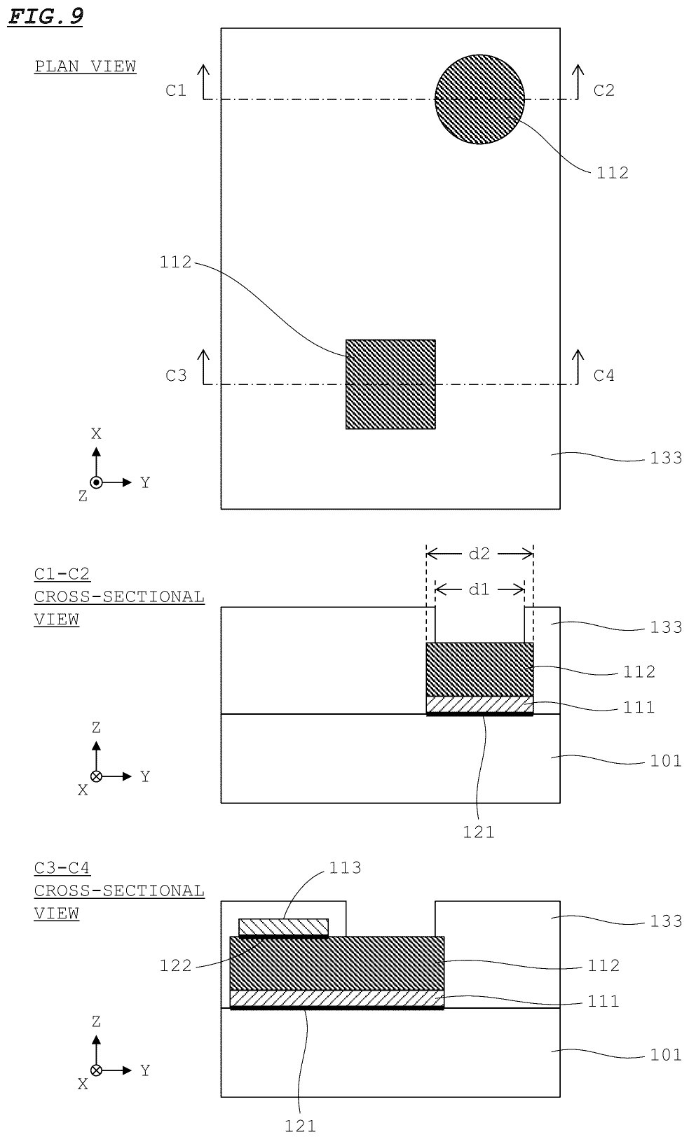

Subsequently, as shown in FIG. 9, a resist 133 is placed in the region other than a region where the piezoelectric layer 112 is to be removed. The region where the piezoelectric layer 112 is to be removed is specifically the ranges of the movable part 40 and the third electrode portions 73 shown in the plan view of FIG. 1. A diameter dl of the region where the piezoelectric layer 112 is to be removed in the movable part 40 is smaller than a diameter d2 of the lower electrode layer 111 of the movable part 40, and the range of the diameter d1 is located within the range of the diameter d2. That is, the resist 133 is placed so as to cover an outer peripheral portion of the piezoelectric layer 112 in the movable part 40. Then, wet etching is performed on the configuration in FIG. 9 from above.

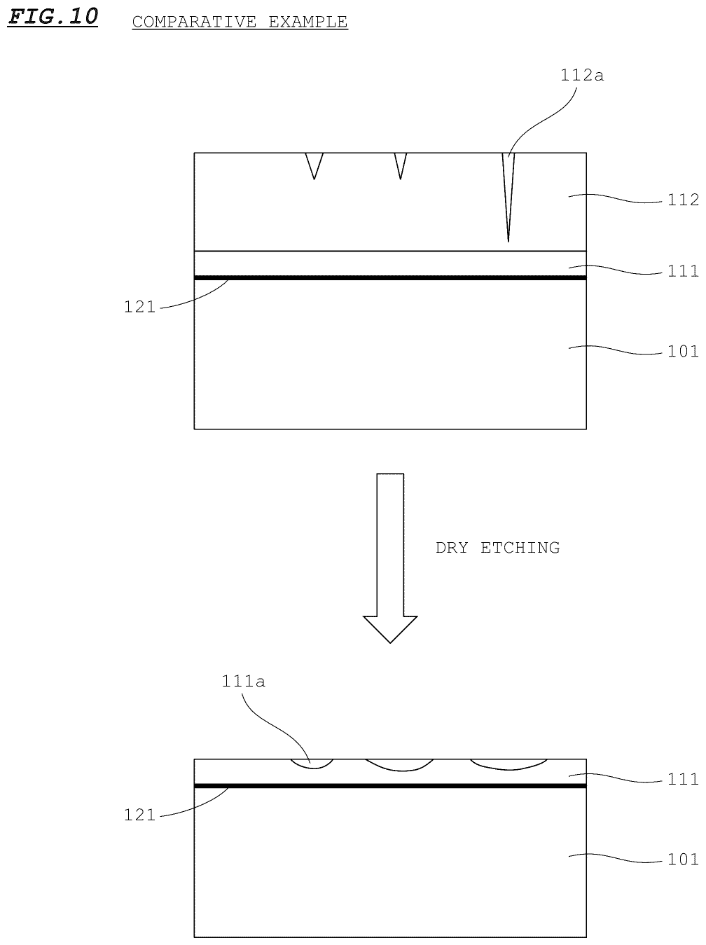

Here, a problem that occurs when dry etching is performed on the configuration in FIG. 9 from above will be described with reference to FIG. 10.

The piezoelectric layer 112 of Embodiment 1 is composed of a single crystal structure of PZT. It is very difficult to form PZT that includes only a single crystal structure, and thus, normally, even if PZT is formed so as to include only a single crystal structure, the PZT includes abnormally grown crystal defects. Therefore, the piezoelectric layer 112 of Embodiment 1 also partially includes crystal defects 112a as shown in the upper part of FIG. 10.

When dry etching is performed on such a piezoelectric layer 112 from above, recesses 111a are formed on the upper surface of the lower electrode layer 111, as shown in the lower part of FIG. 10, due to the difference in etching rate between the portion composed of the single crystal structure and the portions at the crystal defects 112a. If unevenness is formed in the upper surface of the lower electrode layer 111 as described above, the reflectance of the upper surface of the lower electrode layer 111 is significantly decreased. That is, in the case of dry etching, physical etching by ion impact is dominant, and thus selective etching of the piezoelectric layer 112 and the lower electrode layer 111 cannot be carried out, and as a result, the difference in etching rate due to crystal defects in the piezoelectric layer 112 is reflected directly in the lower electrode layer 111, causing unevenness in the lower electrode layer 111.

In contrast, in wet etching, a large difference in etching rate can be created between the piezoelectric layer 112 and the lower electrode layer 111 by a chemical reaction (chemical etching), and thus even if a difference in etching rate occurs in the piezoelectric layer 112 due to crystal defects through wet etching of the piezoelectric layer 112, the difference has very little effect on the lower electrode layer 111.

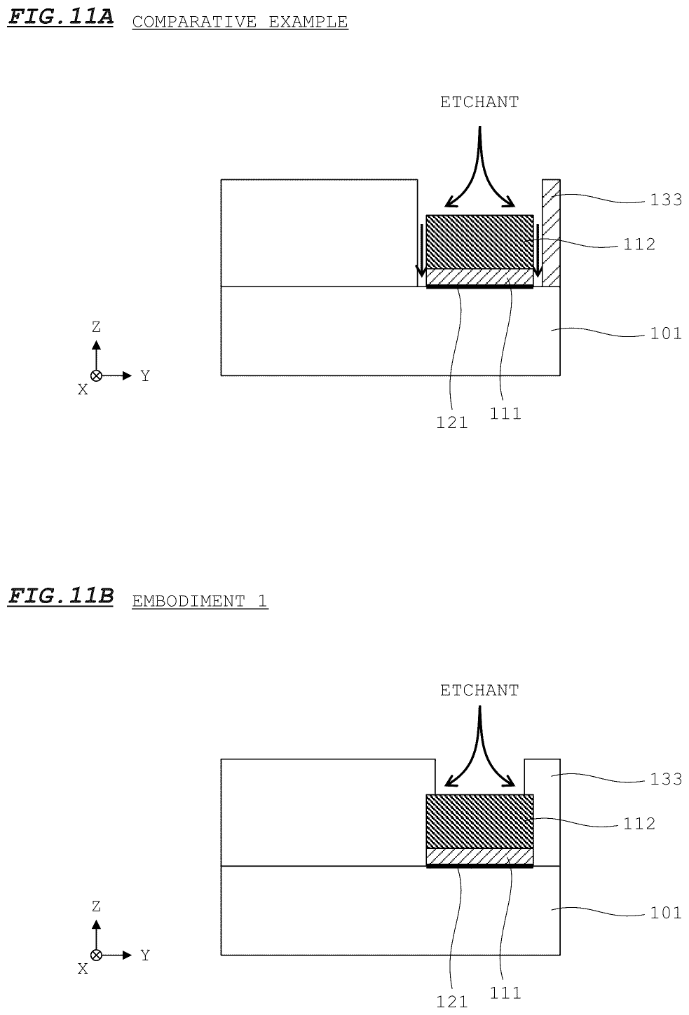

Therefore, in Embodiment 1, wet etching is performed on the configuration in FIG. 9 from above. Accordingly, when the piezoelectric layer 112 is removed, the upper surface of the lower electrode layer 111 can be maintained in a flat state. However, when removing the piezoelectric layer 112 by wet etching in the range of the movable part 40, if the resist 133 is placed so as to match the range of the lower electrode layer 111 as shown in FIG. 11A, peeling of the lower electrode layer 111 is caused. That is, even if the resist 133 is to be placed so as to match the range of the lower electrode layer 111 as shown in FIG. 11A, a gap occurs between the resist 133 and the side surfaces of the lower electrode layer 111 and the piezoelectric layer 112 due to the precision of formation of a resist pattern. In this case, a wet etching etchant (etching solution) for removing the piezoelectric layer 112 enters the interface between the lower electrode layer 111 and the substrate 101 through the side surface of the lower electrode layer 111 and dissolves the adhesion layer 121 (buffer layer) formed at the interface. Accordingly, the lower electrode layer 111 peels off from the substrate 101.

Therefore, in Embodiment 1, as shown in FIG. 9, the resist 133 is placed so as to cover the outer peripheral portion of the lower electrode layer 111 in the range of the movable part 40. Accordingly, as shown in FIG. 11B, no gap occurs between the resist 133 and the side surfaces of the lower electrode layer 111 and the piezoelectric layer 112, so that peeling of the lower electrode layer 111 due to the etchant can be suppressed.

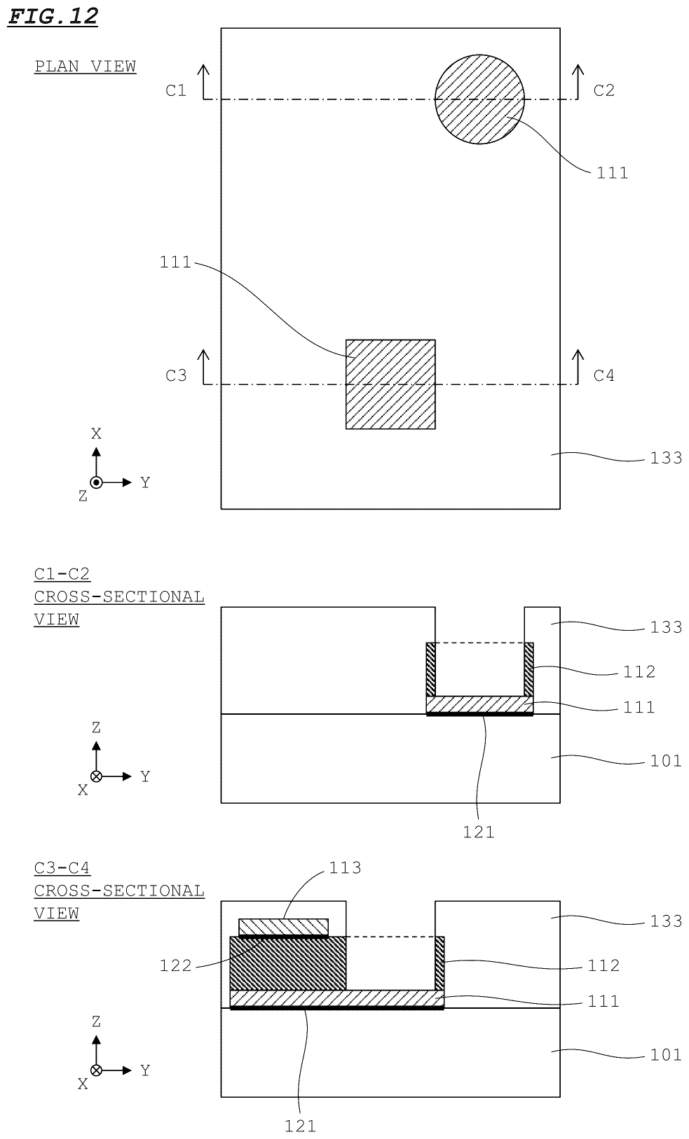

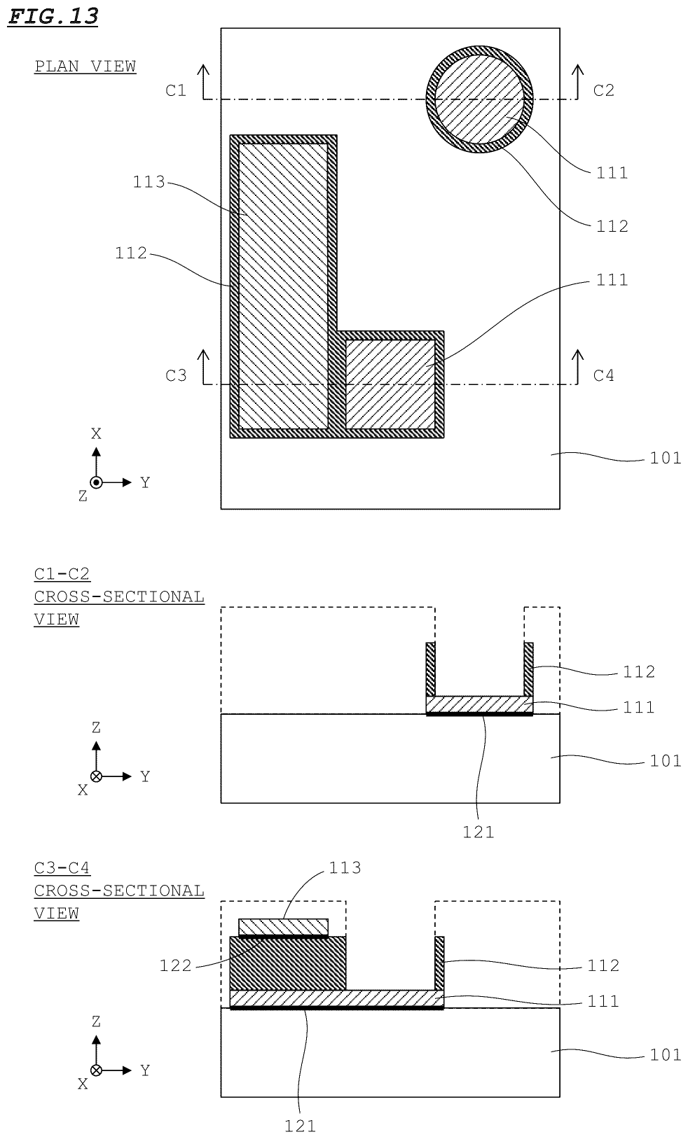

By performing wet etching on the configuration in FIG. 9, the piezoelectric layer 112 is removed in the region other than the region where the resist 132 is placed, as shown in FIG. 12. Then, the resist 133 is removed as shown in FIG. 13. The middle part of FIG. 13 shows the lower electrode layer 111 (the reflection surface 41 in FIG. 2) exposed upward in the movable part 40, and the lower part of FIG. 13 shows the lower electrode layer 111 (the third electrode portion 73 in FIG. 1) exposed upward.

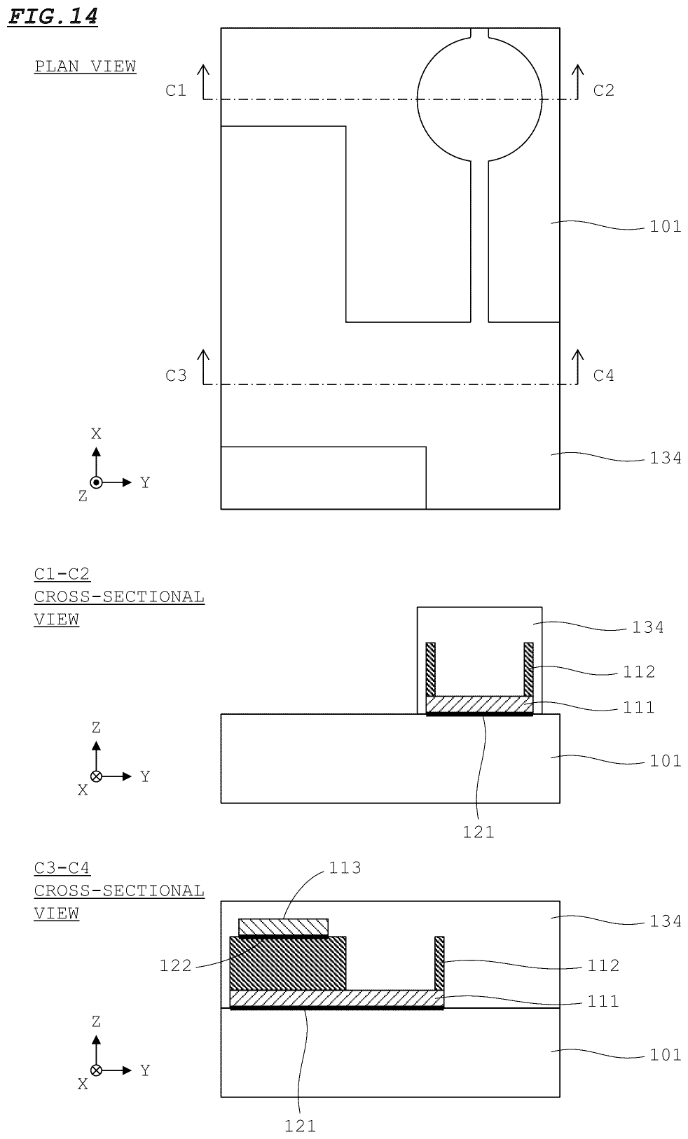

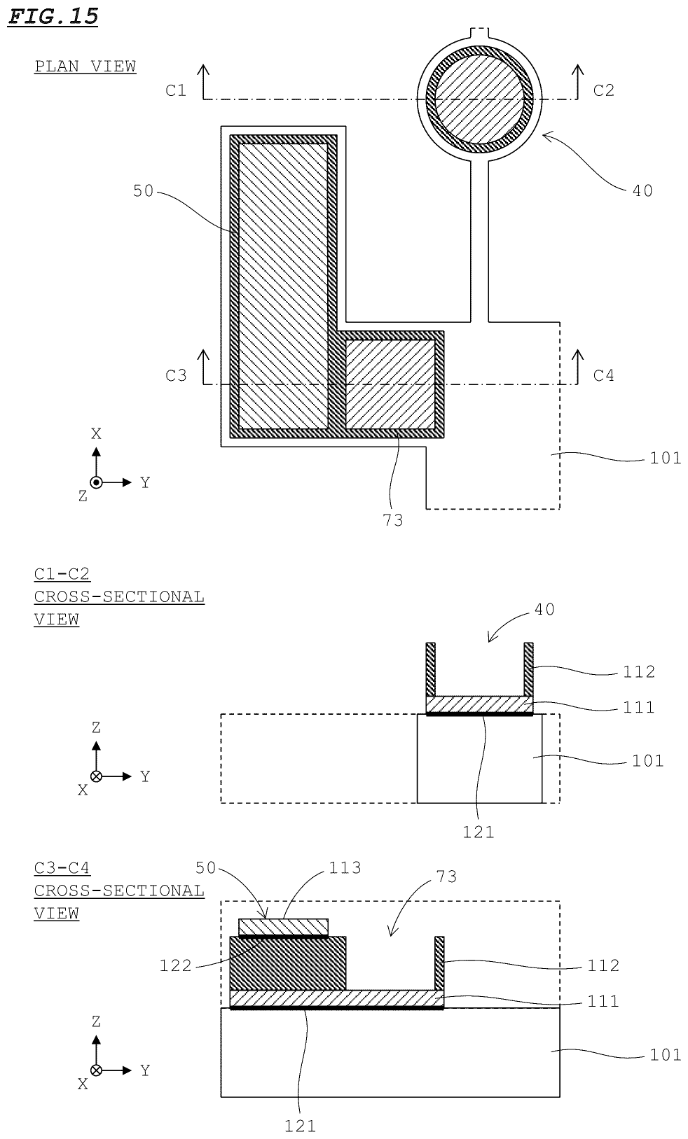

Subsequently, as shown in FIG. 14, a resist 134 is placed in a region where the substrate 101 is to be left. The region where the substrate 101 is to be left is specifically the ranges of all the components shown in the plan view of FIG. 1. Then, dry etching is performed on the configuration in FIG. 14 from above. Accordingly, as shown in FIG. 15, the substrate 101 is removed in the region other than the resist 134, and the resist 134 is then removed. Thus, the optical reflection element 1 is completed.

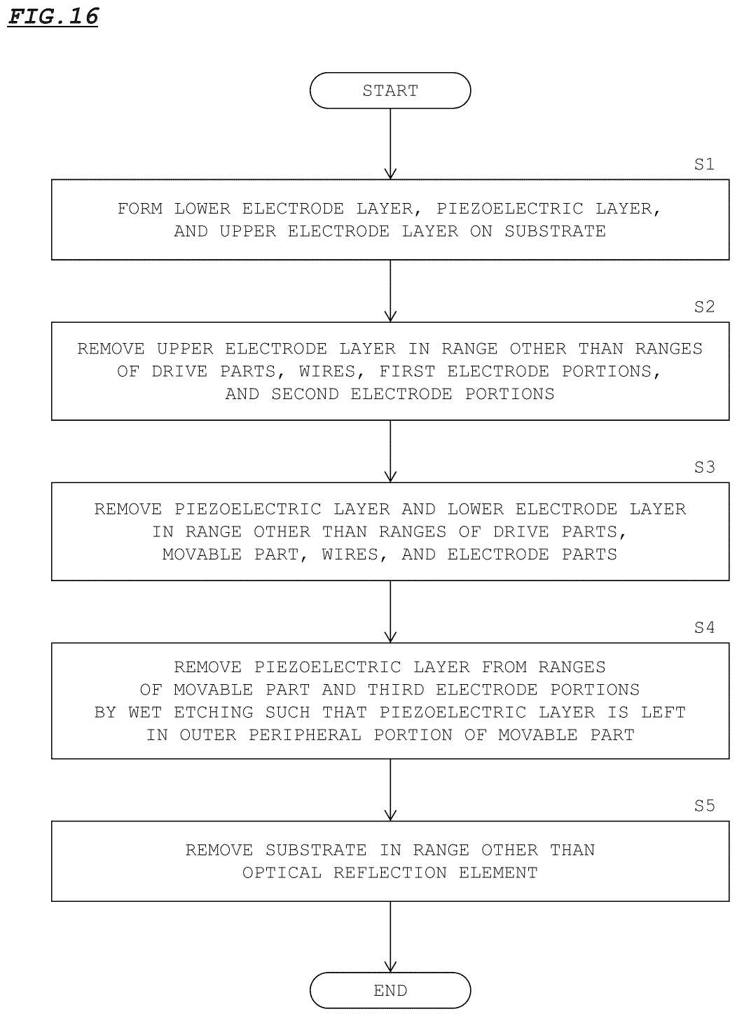

FIG. 16 is a flowchart showing the procedure for forming the optical reflection element 1.

A thermal oxide film is formed on the upper surface of the substrate 101 by thermal oxidation treatment in advance. Then, as shown in FIG. 3, the adhesion layer 121, the lower electrode layer 111, the piezoelectric layer 112, the adhesion layer 122, and the upper electrode layer 113 are stacked in this order from the substrate 101 side on the substrate 101 by a sputtering method to form the non-processed substrate 100 (S1).

Subsequently, as shown in FIG. 4 and FIG. 5, dry etching is performed on the non-processed substrate 100 formed in step S1 such that the upper electrode layer 113 is left in the ranges of the drive parts 50, the detection parts 60, the wires 80, the first electrode portions 71, and the second electrode portions 72, and the upper electrode layer 113 in the range other than these ranges is removed (S2). Subsequently, as shown in FIG. 6 to FIG. 8, dry etching is performed such that the lower electrode layer 111 and the piezoelectric layer 112 are left in the ranges of the movable part 40, the drive parts 50, the detection parts 60, the wires 80, and the electrode parts 70, and the lower electrode layer 111 and the piezoelectric layer 112 in the range other than these ranges are removed (S3).

Subsequently, as shown in FIG. 9, FIG. 12, and FIG. 13, the piezoelectric layer 112 is removed from the movable part 40 and the third electrode portions 73 by wet etching such that the piezoelectric layer 112 is left in the outer peripheral portion 40a of the movable part 40 and (S4). Accordingly, the upper surface of the lower electrode layer 111 is exposed in the movable part 40 and the third electrode portions 73.

Subsequently, as shown in FIG. 14 and FIG. 15, the substrate 101 in the range other than the optical reflection element 1 is removed by dry etching (S5). Thus, the optical reflection element 1 is completed.

### Effects of Embodiment 1

According to Embodiment 1, the following effects are achieved.

As shown in FIG. 2A and FIG. 2B, at least the layer structure that is the same as in the range from the piezoelectric layer 112 to the upper surface of the substrate 101 in the region of the drive part 50 is placed in the region of the outer peripheral portion 40a of the movable part 40, the layer structure that is the same as in the range from the lower electrode layer 111 to the upper surface of the substrate 101 in the region of the drive part 50 is placed in the region of the center portion 40b of the movable part 40, and the upper surface of the lower electrode layer 111 in the region of the center portion 40b is exposed to the outside to constitute the reflection surface 41.

With this configuration, since the lower electrode layer 111 is used as the reflection surface 41, the reflection surface 41 having a high reflectance can be easily formed. In addition, in the region of the outer peripheral portion 40a of the movable part 40, the layer structure that is the same as in the range from the piezoelectric layer 112 to the upper surface of the substrate 101 is placed and made thicker, so that warpage of the reflection surface 41 inside this layer structure is suppressed by this layer structure. Here, the layer structure is placed on the upper surface of the movable part 40 as with the reflection surface 41 and is adjacent to the reflection surface 41, so that warpage of the reflection surface 41 is effectively suppressed by the layer structure. Therefore, the reflection surface 41 whose warpage is effectively suppressed can be stably positioned. Therefore, in the optical reflection element 1 according to Embodiment 1, the reflection surface 41 that has a high reflectance and whose warpage is suppressed can be easily and stably positioned.

As shown in FIG. 3 to FIG. 9, in the method for manufacturing the optical reflection element 1, the lower electrode layer 111, the piezoelectric layer 112, and the upper electrode layer 113 are formed in this order from the substrate 101 side, the upper electrode layer 113 is removed such that the upper electrode layer 113 is left at least in the ranges of the drive parts 50, the lower electrode layer 111 and the piezoelectric layer 112 are removed such that the lower electrode layer 111 and the piezoelectric layer 112 are left at least in the ranges of the drive parts 50 and the movable part 40, the piezoelectric layer 112 is removed from the movable part 40 such that the piezoelectric layer 112 is left in the outer peripheral portion 40a of the movable part 40 to expose the upper surface of the lower electrode layer 111, and the substrate 101 in the range other than the optical reflection element 1 is removed.

With this method, after the layer structure including the lower electrode layer 111, the piezoelectric layer 112, and the upper electrode layer 113 is formed on the substrate 101, each layer of the layer structure is selectively removed by etching, whereby the movable part 40 and the drive parts 50 can be formed together in the same process. Accordingly, device creation can be achieved at low cost. In this formation process, wet etching is applied to the region of the center portion 40b of the movable part 40 to expose the lower electrode layer 111 to the outside, whereby formation of unevenness in the upper surface of the lower electrode layer 111 due to etching can be suppressed, and a reduction in the reflectance of the upper surface can be suppressed. In addition, during this wet etching, at least the layer structure from the piezoelectric layer 112 to the substrate 101 is left in the region of the outer peripheral portion 40a of the movable part 40, so that a resist is placed on the upper side and the outer side of the outer peripheral portion 40a. Therefore, the wet etching etchant does not enter the boundary between the substrate 101 and the lower electrode layer 111 from the outside, and occurrence of peeling in the outer peripheral portion of the lower electrode layer 111 can be suppressed. Therefore, the reflection surface 41 whose reflectance is inhibited from being reduced can be stably positioned on the movable part 40.

The piezoelectric layer 112 is composed of a single crystal structure. With this configuration, piezoelectric characteristics can be enhanced compared to a polycrystalline structure. Therefore, the driving characteristics and the driving efficiency of the movable part 40 can be enhanced.

In the case where the piezoelectric layer 112 has a single crystal structure, if dry etching is applied to the region of the center portion 40b of the movable part 40 to remove the piezoelectric layer 112 as shown in FIG. 10, unevenness is easily formed in the upper surface of the lower electrode layer 111 that is exposed to the outside. In contrast, if wet etching is applied to the region of the center portion 40b of the movable part 40 to remove the piezoelectric layer 112 as in Embodiment 1, formation of unevenness in the upper surface of the lower electrode layer 111 can be suppressed, and the lower electrode layer 111 can be exposed to the outside in a state where a reduction in reflectance is suppressed.

The step of removing the piezoelectric layer 112 from the movable part 40 (step S4 in FIG. 16) includes a step of wet etching.

If the piezoelectric layer 112 in the range of the movable part 40 is removed by dry etching, unevenness is easily formed in the upper surface of the lower electrode layer 111 that is exposed to the outside. In contrast, if the piezoelectric layer 112 in the range of the movable part 40 is removed by wet etching as described above, formation of unevenness in the upper surface of the lower electrode layer 111 can be suppressed, and the lower electrode layer 111 can be exposed to the outside in a state where a reduction in reflectance is suppressed.

### Modification 1 of Embodiment 1

In Embodiment 1, in the movable part 40, only the piezoelectric layer 112 (protrusion 42) is formed on the outer peripheral portion of the lower electrode layer 111, but a monitor electrode 43 composed of an upper electrode layer 113 may be formed on an upper portion of the piezoelectric layer 112.

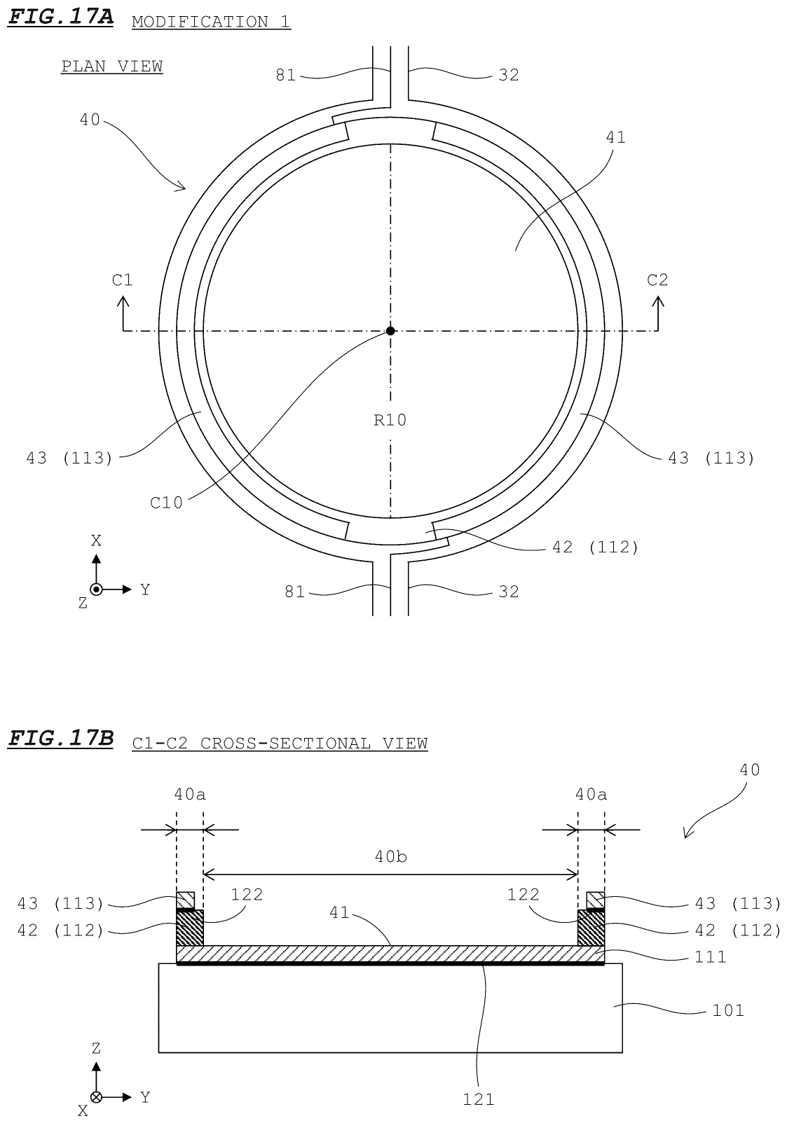

FIG. 17A and FIG. 17B are respectively a plan view and a cross-sectional view schematically showing a configuration of a movable part 40 according to Modification 1 of Embodiment 1. FIG. 17B is a cross-sectional view of a C1-C2 cross-section in the plan view of FIG. 17A as seen in the X-axis positive direction, according to Modification 1 of Embodiment 1.

In Modification 1, compared to Embodiment 1 shown in FIG. 2A and FIG. 2B, a pair of upper electrode layers 113 are left on the upper surface of the piezoelectric layer 112 (protrusion 42) of the movable part 40. The adhesion layer 122 is left between the piezoelectric layer 112 and the upper electrode layer 113. The pair of upper electrode layers 113 each constitute a monitor electrode 43. The pair of monitor electrodes 43 are provided so as to be symmetrical about the rotation axis R10. Wires 81 having the same layer structure as the wires 80 described above are connected to the monitor electrodes 43. Each monitor electrode 43 (upper electrode layer 113) is connected to the upper electrode layer 113 of another electrode portion placed in the electrode part 70 via the upper electrode layer 113 of the wire 81. The other electrode portion is connected to an ammeter, a current detection circuit, or the like in an external device. The lower electrode layer 111 corresponding to each monitor electrode 43 is connected to the lower electrode layer 111 of the third electrode portion 73 via the lower electrode layer 111 of the wire 81.

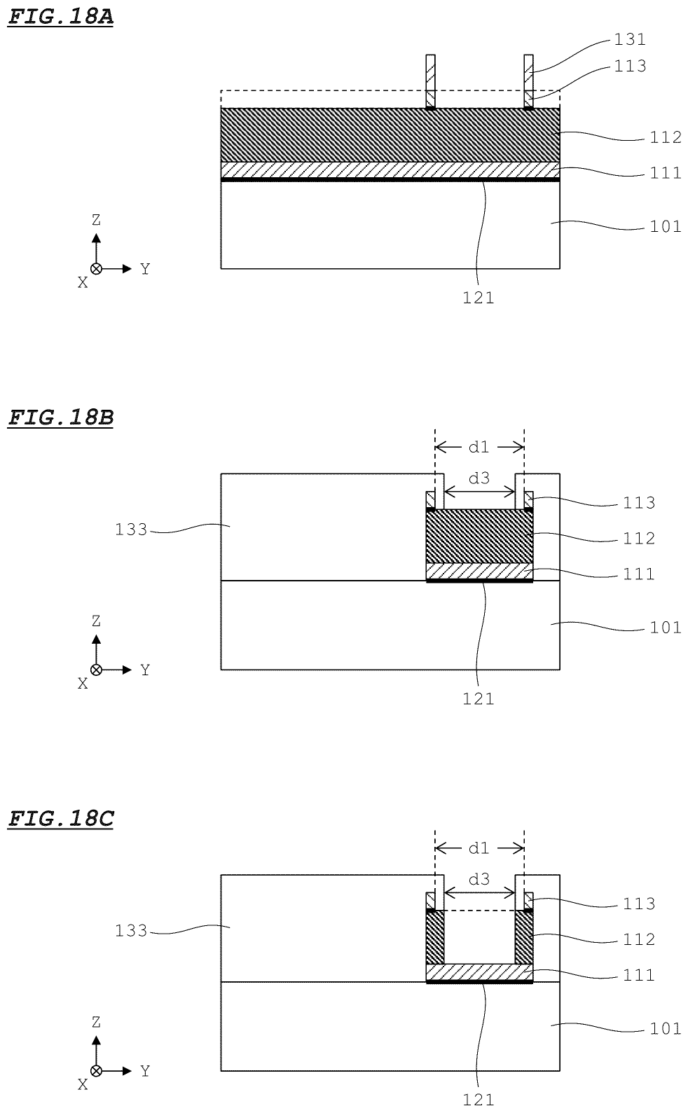

FIG. 18A to FIG. 18C illustrate a procedure for forming the optical reflection element 1 according to Modification 1. Here, for convenience, only the formation procedure different from that of Embodiment 1, in a procedure for forming the movable part 40, will be described.

FIG. 18A is a cross-sectional view corresponding to the drawing in the middle part of FIG. 5, according to Modification 1. In Modification 1, a resist 131 is placed in a region where the upper electrode layer 113 is to be left, and the upper electrode layer 113 in the region other than the resist 131 is removed by dry etching as shown in FIG. 18A.

FIG. 18B is a cross-sectional view corresponding to the drawing in the middle part of FIG. 9, according to Modification 1. In Modification 1 as well, a resist 133 is placed in the region other than a region where the piezoelectric layer 112 is to be removed. At this time, a diameter d3 of the region where the piezoelectric layer 112 is to be removed is smaller than an inner diameter d1 of the upper electrode layer 113, and the range of the diameter d3 is located within the range of the diameter d1. That is, the resist 133 is placed so as to cover the upper electrode layer 113 in the movable part 40. Then, wet etching is performed on the configuration in FIG. 18B from above.

FIG. 18C is a cross-sectional view corresponding to the drawing in the middle part of FIG. 12, according to Modification 1. In Modification 1 as well, by removing the piezoelectric layer 112 in the range of the diameter d3, the lower electrode layer 111 is exposed upward. At this time, the inner diameter d3 of the piezoelectric layer 112 is smaller than the inner diameter d1 of the upper electrode layer 113. Then, as in Embodiment 1, the resist 133 and the unnecessary substrate 101 are removed, so that the optical reflection element 1 is completed.

### Effects of Modification 1 of Embodiment 1

In the region of the outer peripheral portion 40a of the movable part 40, compared to the configuration of Embodiment 1, a layer structure from each upper electrode layer 113 to the upper surface of the piezoelectric layer 112 in the region of the drive part 50 is further placed.

When the movable part 40 rotates, the movable part 40 itself becomes deformed to bend due to an inertial force generated in the movable part 40. The amount of the deformation can be detected due to the piezoelectric effect of the piezoelectric layer 112 placed in the outer peripheral portion 40a. With this configuration, an electrical signal corresponding to the bending and the deflection angle of the piezoelectric layer 112 (protrusion 42) placed in the region of the outer peripheral portion 40a of the movable part 40 can be obtained via the lower electrode layer 111 and each upper electrode layer 113 placed in the region of the outer peripheral portion 40a. Therefore, the bending and the deflection angle of the movable part 40 during driving of the movable part 40 can be detected based on this electrical signal.

Specifically, the bending and the deflection angle of the movable part 40 on the Y-axis negative side of the rotation axis R10 can be detected based on a current detected based on the monitor electrode 43 on the Y-axis negative side of the rotation axis R10, and the bending and the deflection angle of the movable part 40 on the Y-axis positive side of the rotation axis R10 can be detected based on a current detected based on the monitor electrode 43 on the Y-axis positive side of the rotation axis R10.

In the above configuration, the other electrode portion of the electrode part 70 connected to each upper electrode layer 113 (monitor electrode 43) is connected to the ammeter, the current detection circuit, or the like in the external device, but the present invention is not limited thereto, and the other electrode portion of the electrode part 70 may be connected to a power supply, a power supply circuit, or the like in the external device. In this case, each upper electrode layer 113 of the movable part 40 constitutes a correction electrode. With this configuration, by applying a voltage to the piezoelectric layer 112 via the lower electrode layer 111 and each upper electrode layer 113 placed in the region of the outer peripheral portion 40a of the movable part 40, the piezoelectric layer 112 can be caused to expand and contract due to an inverse piezoelectric effect. Therefore, the bending of the movable part 40 during driving of the movable part 40 can be corrected by this expansion and contraction.

Specifically, the bending of the movable part 40 on the Y-axis negative side of the rotation axis R10 can be corrected by applying a voltage to the piezoelectric layer 112 corresponding to the correction electrode on the Y-axis negative side, and the bending of the movable part 40 on the Y-axis positive side of the rotation axis R10 can be corrected by applying a voltage to the piezoelectric layer 112 corresponding to the correction electrode on the Y-axis positive side.

The upper electrode layers 113 in the region of the outer peripheral portion 40a of the movable part 40 are provided so as to be symmetrical about the rotation axis R10.

With this configuration, the bending and the deflection angle of the movable part 40 with respect to the rotation axis R10 from a neutral state can be smoothly detected. In addition, in the case where each upper electrode layer 113 of the movable part 40 constitutes the correction electrode, the bending of the movable part 40 with respect to the rotation axis R10 from the neutral state can be smoothly corrected.

As shown in FIG. 18A, in the step of removing the upper electrode layer 113, the upper electrode layer 113 is also left in the outer peripheral portion 40a of the movable part 40. As shown in FIG. 18B and FIG. 18C, in the step of removing the piezoelectric layer 112 from the movable part 40, the piezoelectric layer 112 is removed such that the upper electrode layer 113 and the piezoelectric layer 112 are left in the outer peripheral portion 40a of the movable part 40.

As a result of this process, an electrical signal corresponding to the bending and the deflection angle of the piezoelectric layer 112 of the movable part 40 can be obtained by the lower electrode layer 111 and each upper electrode layer 113 (monitor electrode 43) of the movable part 40. Therefore, the bending and the deflection angle of the movable part 40 during driving of the movable part 40 can be detected based on this electrical signal. In addition, in the case where each upper electrode layer 113 of the movable part 40 constitutes the correction electrode, the piezoelectric layer 112 of the movable part 40 can be caused to expand and contract by applying a voltage to the piezoelectric layer 112 via the lower electrode layer 111 and each upper electrode layer 113 (correction electrode) of the movable part 40. Therefore, the bending of the movable part 40 during driving of the movable part 40 can be corrected by this expansion and contraction.

In addition, as shown in FIG. 18B, by placing the resist 133 such that the resist 133 covers each upper electrode layer 113, dissolution of the adhesion layer 122 by an etchant for wet etching on the piezoelectric layer 112 can be avoided. Accordingly, each upper electrode layer 113 can be prevented from peeling off from the piezoelectric layer 112.

### Modification 2 Embodiment 1

In Modification 1 of Embodiment 1, each monitor electrode 43 is formed on the upper portion of the piezoelectric layer 112, but a correction electrode 44 may be further placed thereon.

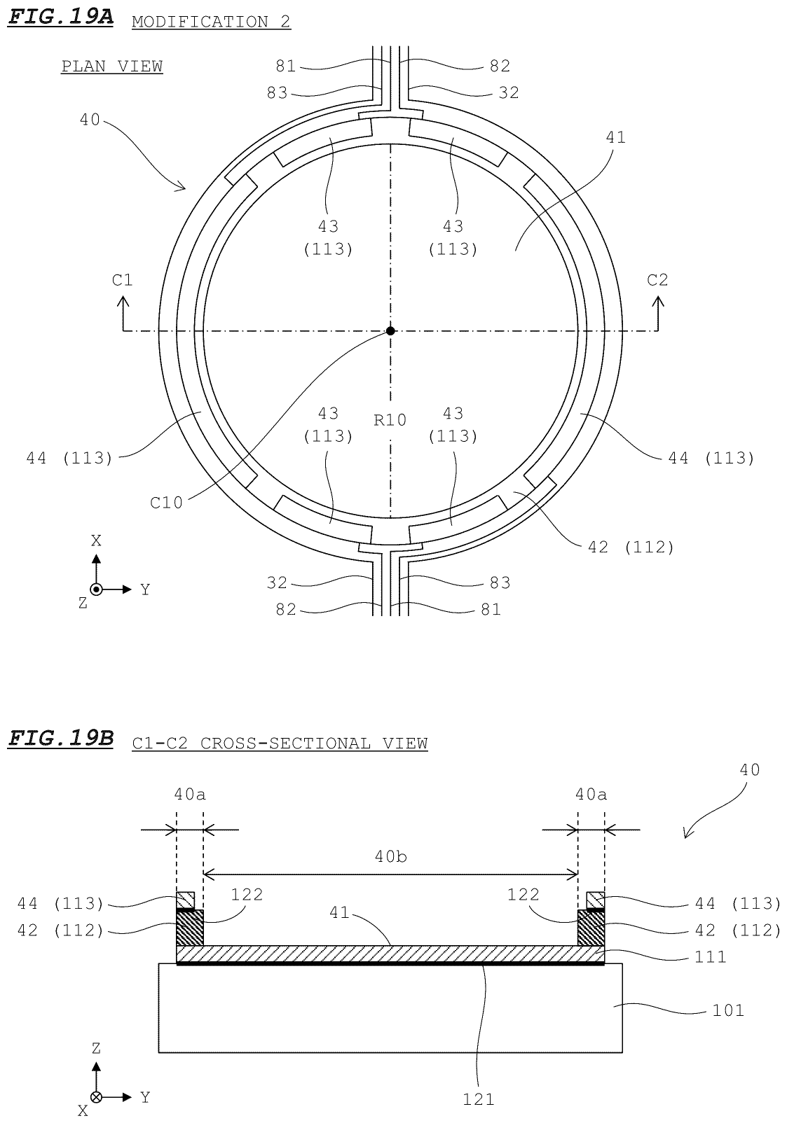

FIG. 19A and FIG. 19B are respectively a plan view and a cross-sectional view schematically showing a configuration of a movable part 40 according to Modification 2 of Embodiment 1.

In Modification 2, compared to Modification 1 shown in FIG. 17A and FIG. 17B, three pairs of upper electrode layers 113 are left on the upper surface of the piezoelectric layer 112 (protrusion 42) of the movable part 40.

Two pairs of upper electrode layers 113 located away from a C1-C2 cross-section constitute monitor electrodes 43. A pair of upper electrode layers 113 located at a position intersecting the C1-C2 cross-section constitute correction electrodes 44. The two pairs of monitor electrodes 43 and the pair of correction electrodes 44 are provided so as to be symmetrical about the rotation axis R10.

The monitor electrodes 43 and the correction electrodes 44 have the same layer structure as the monitor electrodes 43 of Modification 1 described above. Wires 81 to 83 have the same layer structure as the wires 81 of Modification 1 described above.

The two monitor electrodes 43 (upper electrode layers 113) located on the X-axis positive side of the C1-C2 cross-section and the one correction electrode 44 (upper electrode layer 113) on the Y-axis negative side are connected to the upper electrode layers 113 of different other electrode portions provided in the electrode part 70 on the X-axis positive side via the wires 81, 82, and 83, respectively. The lower electrode layers 111 corresponding to these two monitor electrodes 43 and this one correction electrode 44 are connected to the lower electrode layers 111 of the third electrode portions 73 provided in the electrode part 70 on the X-axis positive side via the lower electrode layers 111 of the wires 81, 82, and 83, respectively.

The two monitor electrodes 43 (upper electrode layers 113) located on the X-axis negative side of the C1-C2 cross-section and the one correction electrode 44 (upper electrode layer 113) on the Y-axis positive side are connected to the upper electrode layers 113 of different other electrode portions provided in the electrode part 70 on the X-axis negative side via the wires 81, 82, and 83, respectively. The lower electrode layers 111 corresponding to these two monitor electrodes 43 and this one correction electrode 44 are connected to the lower electrode layers 111 of the third electrode portions 73 provided in the electrode part 70 on the X-axis negative side via the lower electrode layers 111 of the wires 81, 82, and 83, respectively.

Each of the above other electrode portions to which the four monitor electrodes 43 are connected is connected to an ammeter, a current detection circuit, or the like in an external device. Each of the above other electrode portions to which the two correction electrode 44 are connected is connected to a power supply, a power supply circuit, or the like in the external device.

### Effects of Modification 2 of Embodiment 1

In the region of the outer peripheral portion 40a of the movable part 40, the two pairs of monitor electrodes 43 and the pair of correction electrodes 44 each composed of the upper electrode layer 113 are placed.

With this configuration, an electrical signal corresponding to the bending and the deflection angle of the piezoelectric layer 112 (protrusion 42) placed in the region of the outer peripheral portion 40a of the movable part 40 can be obtained by the lower electrode layer 111 and each upper electrode layer 113 (monitor electrode 43) placed in the region of the outer peripheral portion 40a. Therefore, the bending and the deflection angle of the movable part 40 during driving of the movable part 40 can be detected based on this electrical signal. In addition, by applying a voltage to the piezoelectric layer 112 via the lower electrode layer 111 and each upper electrode layer 113 (correction electrode 44) placed in the region of the outer peripheral portion 40a of the movable part 40, the piezoelectric layer 112 can be caused to expand and contract. Therefore, the bending of the movable part 40 during driving of the movable part 40 can be corrected by this expansion and contraction.

Specifically, the bending and the deflection angle of the movable part 40 on the Y-axis negative side of the rotation axis R10 can be detected based on a current detected based on the two monitor electrodes 43 on the Y-axis negative side of the rotation axis R10, and the bending and the deflection angle of the movable part 40 on the Y-axis positive side of the rotation axis R10 can be detected based on a current detected based on the two monitor electrodes 43 on the Y-axis positive side of the rotation axis R10. In addition, the bending of the movable part 40 on the Y-axis negative side of the rotation axis R10 can be corrected by applying a voltage to the piezoelectric layer 112 corresponding to the correction electrode 44 on the Y-axis negative side, and the bending of the movable part 40 on the Y-axis positive side of the rotation axis R10 can be corrected by applying a voltage to the piezoelectric layer 112 corresponding to the correction electrode 44 on the Y-axis positive side.

In Modification 2, the upper electrode layers 113 constituting the monitor electrodes 43 may be used as correction electrodes, and the upper electrode layers 113 constituting the correction electrodes 44 may be used as monitor electrodes.

The upper electrode layers 113 of the movable part 40 are provided so as to be symmetrical about the rotation axis R10.

With this configuration, the bending and the deflection angle of the movable part 40 with respect to the rotation axis R10 from a neutral state can be smoothly detected, and the bending of the movable part 40 with respect to the rotation axis R10 from the neutral state can be smoothly corrected.

### Modification 3 of Embodiment 1

In Embodiment 1, the protrusion 42 is formed in a ring shape, but the shape of the protrusion 42 is not limited to the ring shape. For example, a projection portion 42a may be formed on the inner surface of a ring-shaped portion of the protrusion 42.

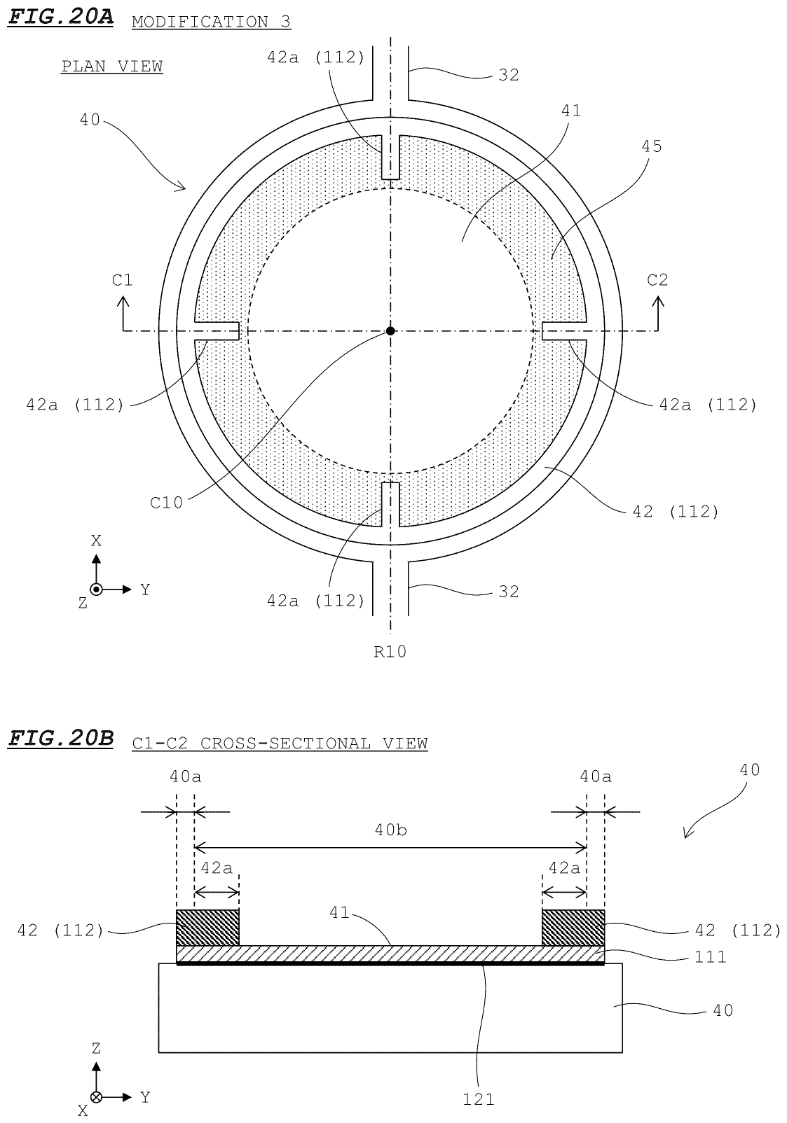

FIG. 20A and FIG. 20B are respectively a plan view and a cross-sectional view schematically showing a configuration of a movable part 40 according to Modification 3 of Embodiment 1.

In Modification 3, compared to Embodiment 1 shown in FIG. 2A and FIG. 2B, the projection portion 42a is formed by a part of the inner surface of the protrusion 42 (piezoelectric layer 112) of the movable part 40 protruding inward. In the example of FIG. 20A and FIG. 20B, two projection portions 42a are formed at positions overlapping the rotation axis R10, and two projection portions 42a are formed at positions overlapping a C1-C2 cross-section. An air retention portion 45 for retaining air is formed in a region surrounded by the inner surface of the protrusion 42 and the side surfaces of the multiple projection portions 42a. In FIG. 20A, for convenience, a region corresponding to the air retention portion 45 is hatched.

### Effects of Modification 3 of Embodiment 1

The air retention portion 45 for retaining air is formed by causing the protrusion 42 (piezoelectric layer 112), which is placed in the outer peripheral portion 40a of the movable part 40, to protrude toward the center portion 40b.

With this configuration, even if dust exists near the upper surface of the lower electrode layer 111 constituting the reflection surface 41 on the movable part 40, this dust is retained in the air retention portion 45. Accordingly, a reduction in the reflectance of the reflection surface 41 can be suppressed.

### Embodiment 2

In Embodiment 1, the vibration parts 21 and 22 are placed in a tuning fork shape, but in Embodiment 2, vibration parts are placed in a meander shape.

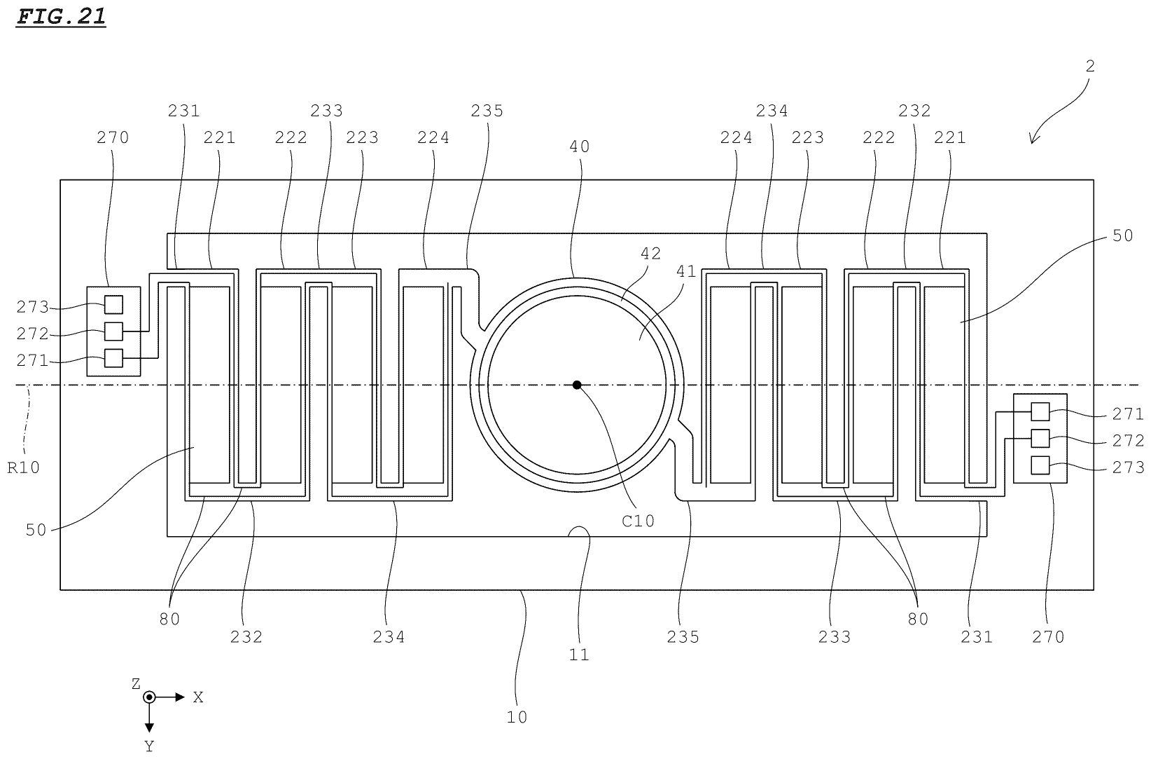

FIG. 21 is a plan view schematically showing a configuration of an optical reflection element 2 according to Embodiment 2.

The optical reflection element 2 includes a fixation part 10, a pair of sets of vibration parts 221 to 224, a pair of sets of connection parts 231 to 235, a movable part 40, eight drive parts 50, ten wires 80, and a pair of electrode parts 270. The optical reflection element 2 is configured to be point-symmetrical about a center C10 thereof. Hereinafter, for convenience, the same components as in Embodiment 1 are denoted by the same reference characters.

The pair of sets of vibration parts 221 to 224 and the pair of sets of connection parts 231 to 235 are placed between a frame-shaped inner portion of the fixation part 10 and the movable part 40 in a plan view. A set of the vibration parts 221 to 224 and the connection parts 231 to 235 is placed on each of the X-axis positive side and the X-axis negative side of the movable part 40. The vibration parts 221 to 224 located on the X-axis positive side or the X-axis negative side of the movable part 40 have a meander shape in a plan view.

The vibration parts 221 to 224 each have a rectangular shape that is longer in the Y-axis direction than in the X-axis direction. The vibration part 221 on the X-axis negative side of the movable part 40 is connected at an end portion thereon on the Y-axis negative side to the fixation part 10 by the connection part 231. The vibration part 222 on the X-axis negative side of the movable part 40 is connected at an end portion thereof on the Y-axis positive side to the vibration part 221 by the connection part 232. The vibration part 223 on the X-axis negative side of the movable part 40 is connected at an end portion thereof on the Y-axis negative side to the vibration part 222 by the connection part 233. The vibration part 224 on the X-axis negative side of the movable part 40 is connected at an end portion thereof on the Y-axis positive side to the vibration part 223 by the connection part 234. The vibration part 224 on the X-axis negative side of the movable part 40 is connected at an end portion thereof on the Y-axis negative side to the movable part 40 by the connection part 235. The vibration parts 221 to 224 and the connection parts 231 to 235 on the X-axis positive side of the movable part 40 are configured to be point-symmetrical to the vibration parts 221 to 224 and the connection parts 231 to 235 on the X-axis negative side of the movable part 40 about the center C10.

Four drive parts 50 are placed on the upper surfaces of the vibration parts 221 to 224 on the X-axis negative side of the movable part 40, and four drive parts 50 are placed on the upper surfaces of the vibration parts 221 to 224 on the X-axis positive side of the movable part 40. Each drive part 50 is connected to a first electrode portion 271 or a second electrode portion 272 of the electrode part 270 via the wire 80. The drive parts 50 and the wires 80 each have the same layer structure as in Embodiment 1. Each electrode part 270, each first electrode portion 271, each second electrode portion 272, and each third electrode portion 273 have the same layer structure as each electrode part 70, each first electrode portion 71, each second electrode portion 72, and each third electrode portion 73 of Embodiment 1. Cables (external wires) connected to an external device are connected to the upper surfaces of each first electrode portion 271, each second electrode portion 272, and each third electrode portion 273 by wire bonding. Each of the first electrode portion 271 and the second electrode portion 272 is connected to a power supply, a power supply circuit, or the like in the external device. The third electrode portion 273 is connected to a ground in the external device.

When drive voltages are applied via the first electrode portions 271 to the drive parts 50 on the vibration parts 221 and 223 connected to the first electrode portions 271, the piezoelectric layers 112 in these drive parts 50 become deformed, so that the vibration parts 221 and 223 become deformed so as to bend. Meanwhile, when drive voltages are applied via the second electrode portions 272 to the drive parts 50 on the vibration parts 222 and 224 connected to the second electrode portions 272, the piezoelectric layers 112 in these drive parts 50 become deformed, so that the vibration parts 222 and 224 become deformed so as to bend. Accordingly, due to the deformation of the vibration parts 221 to 224, the movable part 40 rotates about the rotation axis R10.

Either each first electrode portion 271 or each second electrode portion 272 may be connected to an ammeter, a current detection circuit, or the like in the external device. In this case, the drive part 50 connected to the electrode connected to the ammeter or the like, out of each first electrode portion 271 and each second electrode portion 272, constitutes a detection part, and the bending of the vibration part on which the detection part is placed can be detected based on a detected current value.

In Embodiment 2 as well, the movable part 40 is configured in the same manner as in Embodiment 1, so that the same effects as those of Embodiment 1 are achieved. In addition, in Embodiment 2 as well, the movable part 40 may be configured in the same manner as in Modifications 1 to 3 of Embodiment 1. In this case as well, the same effects as those of Modifications 1 to 3 of Embodiment 1 are achieved.

### Other Modifications

In the above embodiments and modifications, the piezoelectric layer 112 is composed of a single crystal structure of PZT but is not limited thereto and may be composed of a polycrystalline structure of PZT. When the piezoelectric layer 112 made of PZT with a polycrystalline structure is removed by dry etching, the degree to which unevenness occurs in the upper surface of the lower electrode layer 111 is lower than when the piezoelectric layer 112 made of PZT with a single crystal structure is removed by dry etching. However, unevenness can still be formed in the upper surface of the lower electrode layer 111. Therefore, even in the case where the piezoelectric layer 112 is composed of a polycrystalline structure of PZT, it is preferable that the piezoelectric layer 112 in the range of the movable part 40 is removed by wet etching as in the above embodiments and modifications.

In the above embodiments and modifications, the piezoelectric layer 112 is made of PZT but may be made of another material having a piezoelectric effect. In this case as well, it is preferable that the other material having a piezoelectric effect is composed of a single crystal structure. Accordingly, the driving characteristics and the driving efficiency of the movable part 40 can be enhanced. In addition, in the case where the other material having a piezoelectric effect is composed of a single crystal structure, it is preferable that the piezoelectric layer 112 in the range of the movable part 40 is removed by wet etching. Accordingly, formation of unevenness in the upper surface of the lower electrode layer 111 can be suppressed.

In the above embodiments and modifications, the outer peripheral portion 40a of the movable part 40 is located inside the outer edge of the substrate 101 but is not limited thereto and may be located along the outer edge of the substrate 101. That is, in the movable part 40, the outer edges of the lower electrode layer 111 and the piezoelectric layer 112 may coincide with the outer edge of the substrate 101.

In the above embodiments and modifications, the piezoelectric layer 112 of the movable part 40 is placed over the entire circumference of the outer peripheral portion 40a but may be placed over only a part of the outer peripheral portion 40a. In this case as well, peeling of the lower electrode layer 111 by the wet etching etchant at the position of the outer peripheral portion 40a where the piezoelectric layer 112 is placed can be suppressed. However, when the piezoelectric layer 112 is placed over the entire circumference of the outer peripheral portion 40a as in the above embodiments and modifications, peeling of the lower electrode layer 111 by the wet etching etchant can be reliably suppressed.

In the above embodiments and modifications, the lower electrode layer 111 is made of platinum (Pt) but may be made of another material having electrical conductivity. The upper electrode layer 113 is made of gold (Au) but may be made of another material having electrical conductivity. The adhesion layers 121 and 122 are made of titanium (Ti) but may be made of chromium (Cr) or tungsten (W).

In Embodiments 1 and 2 described above, two drive units are placed with the movable part 40 located therebetween as shown in FIG. 1 and FIG. 21, but one of the two drive units may be omitted. For example, in Embodiment 1 shown in FIG. 1, the components on the X-axis positive side of the movable part 40 may be omitted, and the movable part 40 may be supported by the connection part 31 on the X-axis negative side. In Embodiment 2 shown in FIG. 21, the components on the X-axis positive side of the movable part 40 may be omitted, and the movable part 40 may be supported by the connection part 235 on the X-axis negative side.

In Embodiments 1 and 2 described above, the annular protrusion 42 (piezoelectric layer 112) is placed over the entire range of the region of the outer peripheral portion 40a of the movable part 40, but a part of the protrusion 42 (piezoelectric layer 112) may be omitted as long as warpage of the reflection surface 41 can be suppressed.

From the viewpoint of suppressing peeling of the outer peripheral portion of the lower electrode layer 111 and stably positioning the reflection surface 41, the entirety of the protrusion 42 (piezoelectric layer 112) may be removed after the optical reflection element 1 or 2 is formed by the manufacturing method in FIG. 3 to FIG. 9. Regardless of how the piezoelectric layer formed in the region of the outer peripheral portion of the movable part by the manufacturing method of the present invention is processed afterward, this manufacturing process can be included in the technical scope of the manufacturing method of the present invention as long as the entirety of the manufacturing method of the present invention is carried out.

In Embodiments 1 and 2 described above, warpage of the reflection surface 41 is suppressed by placing the protrusion 42 (piezoelectric layer 112) in the region of the outer peripheral portion 40a of the movable part 40, but the present invention does not exclude placement of a component for suppressing warpage of the reflection surface 41, in the region other than the outer peripheral portion 40a of the movable part 40. In the case where the thickness of the piezoelectric layer 112 is small and the height of the protrusion 42 is low, a rib for suppressing warpage of the reflection surface 41 may be further placed on the lower surface of the movable part 40 to enhance the effect of suppressing warpage of the reflection surface 41. Also, in the case where the entirety of the protrusion 42 (piezoelectric layer 112) is removed after the optical reflection element 1 or 2 is formed by the manufacturing method in FIG. 3 to FIG. 9 as described above, a rib for suppressing warpage of the reflection surface 41 may be placed on the lower surface of the movable part 40.

In addition to the above, various modifications can be made as appropriate to the embodiments of the present invention without departing from the scope of the technical idea defined by the claims.

### (Additional Note)

The following technologies are disclosed by the description of the above embodiments.

### (Technology 1)

An optical reflection element including:
a movable part; and
a drive part configured to rotate the movable part about a rotation axis, wherein
a lower electrode layer, an upper electrode layer located above the lower electrode layer, and a piezoelectric layer located between the lower electrode layer and the upper electrode layer are placed in a region of the drive part on a substrate that forms an outer shell of the optical reflection element,
at least a layer structure that is the same as in a range from the piezoelectric layer to an upper surface of the substrate in the region of the drive part is placed in a region of an outer peripheral portion of the movable part on the substrate,
a layer structure that is the same as in a range from the lower electrode layer to the upper surface of the substrate in the region of the drive part is placed in a region of a center portion of the movable part on the substrate, and
an upper surface of the lower electrode layer in the region of the center portion is exposed to outside to constitute a reflection surface.

According to this technology, since the lower electrode layer is used as the reflection surface, the reflection surface having a high reflectance can be easily formed. In addition, in the region of the outer peripheral portion of the movable part, the layer structure that is the same as in the range from the piezoelectric layer to the upper surface of the substrate is placed and made thicker, so that warpage of the reflection surface inside this layer structure is suppressed by this layer structure. Here, the layer structure is placed on the upper surface of the movable part as with the reflection surface and is adjacent to the reflection surface, so that warpage of the reflection surface is effectively suppressed by the layer structure. Therefore, the reflection surface whose warpage is effectively suppressed can be stably positioned. Therefore, in the optical reflection element according to this aspect, the reflection surface that has a high reflectance and whose warpage is suppressed can be easily and stably positioned.

### (Technology 2)

The optical reflection element according to technology 1, wherein a layer structure from the upper electrode layer to an upper surface of the piezoelectric layer in the region of the drive part is further placed in the region of the outer peripheral portion of the movable part.

According to this technology, an electrical signal corresponding to the bending and the deflection angle of the piezoelectric layer placed in the region of the outer peripheral portion of the movable part can be obtained via the lower electrode layer and the upper electrode layer placed in the region of the outer peripheral portion. Therefore, the bending and the deflection angle of the movable part during driving of the movable part can be detected based on this electrical signal. In addition, the piezoelectric layer can be caused to expand and contract by applying a voltage to the piezoelectric layer via the lower electrode layer and the upper electrode layer placed in the region of the outer peripheral portion of the movable part. Therefore, the bending of the movable part during driving of the movable part can be corrected by this expansion and contraction.

### (Technology 3)

The optical reflection element according to technology 2, wherein the upper electrode layer in the region of the outer peripheral portion of the movable part is provided so as to be symmetrical about the rotation axis.

According to this technology, the bending and the deflection angle of the movable part with respect to the rotation axis from a neutral state can be smoothly detected, and the bending of the movable part with respect to the rotation axis from the neutral state can be smoothly corrected.

### (Technology 4)

The optical reflection element according to any one of technologies 1 to 3, wherein an air retention portion for retaining air is formed by causing the piezoelectric layer placed in the outer peripheral portion of the movable part to protrude toward the center portion.

According to this technology, even if dust exists near the upper surface of the lower electrode layer constituting the reflection surface on the movable part, this dust is retained in the air retention portion. Accordingly, a reduction in the reflectance of the reflection surface can be suppressed.

### (Technology 5)

The optical reflection element according to any one of technologies 1 to 4, wherein the piezoelectric layer is composed of a single crystal structure.

According to this technology, piezoelectric characteristics can be enhanced compared to a polycrystalline structure. Therefore, the driving characteristics and the driving efficiency of the movable part can be enhanced.

### (Technology 6)

A method for manufacturing an optical reflection element, including the steps of:
forming a lower electrode layer, a piezoelectric layer, and an upper electrode layer in this order from a substrate side;
removing the upper electrode layer such that the upper electrode layer is left at least in a range of a drive part;
removing the lower electrode layer and the piezoelectric layer such that the lower electrode layer and the piezoelectric layer are left at least in the range of the drive part and a range of a movable part;
removing the piezoelectric layer from the movable part such that the piezoelectric layer is left in an outer peripheral portion of the movable part to expose an upper surface of the lower electrode layer; and
removing the substrate in a range other than the optical reflection element.

According to this technology, after the layer structure including the lower electrode layer, the piezoelectric layer, and the upper electrode layer is formed on the substrate, each layer of the layer structure is selectively removed by etching, whereby the movable part and the drive part can be formed together in the same process. Accordingly, device creation can be achieved at low cost. In this formation process, wet etching is applied to the region of the center portion of the movable part to expose the lower electrode layer to the outside, whereby formation of unevenness in the upper surface of the lower electrode layer due to etching can be suppressed, and a reduction in the reflectance of the upper surface can be suppressed. In addition, during this wet etching, at least the layer structure from the piezoelectric layer to the substrate is left in the region of the outer peripheral portion of the movable part, so that a resist is placed on the upper side and the outer side of the outer peripheral portion. Therefore, the wet etching etchant does not enter the boundary between the substrate and the lower electrode layer from the outside, and occurrence of peeling in the outer peripheral portion of the lower electrode layer can be suppressed. Therefore, the reflection surface whose reflectance is inhibited from being reduced can be stably positioned on the movable part.

### (Technology 7)

The method for manufacturing the optical reflection element according to technology 6, wherein
in the step of removing the upper electrode layer, the upper electrode layer is also left in the outer peripheral portion of the movable part, and
in the step of removing the piezoelectric layer from the movable part, the piezoelectric layer is removed such that the upper electrode layer and the piezoelectric layer are left in the outer peripheral portion of the movable part.

According to this technology, an electrical signal corresponding to the bending and the deflection angle of the piezoelectric layer of the movable part can be obtained by the lower electrode layer and the upper electrode layer of the movable part. Therefore, the bending and the deflection angle of the movable part during driving of the movable part can be detected based on this electrical signal. In addition, the piezoelectric layer of the movable part can be caused to expand and contract by applying a voltage to the piezoelectric layer via the lower electrode layer and the upper electrode layer of the movable part. Therefore, the bending of the movable part during driving of the movable part can be corrected by this expansion and contraction.

### (Technology 8)

The method for manufacturing the optical reflection element according to technology 6 or 7, wherein the step of removing the piezoelectric layer from the movable part includes a step of wet etching.

If the piezoelectric layer in the range of the movable part is removed by dry etching, unevenness is easily formed in the upper surface of the lower electrode layer that is exposed to the outside. In contrast, according to the above technology, if the piezoelectric layer in the range of the movable part is removed by wet etching, formation of unevenness in the lower electrode layer can be suppressed, and the lower electrode layer can be exposed to the outside in a state where a reduction in reflectance is suppressed.

What is claimed is:

1. An optical reflection element comprising:
a movable part; and
a drive part configured to rotate the movable part about a rotation axis, wherein
a lower electrode layer, an upper electrode layer located above the lower electrode layer, and a piezoelectric layer located between the lower electrode layer and the upper electrode layer are placed in a region of the drive part on a substrate that forms an outer shell of the optical reflection element,
at least a layer structure that is the same as in a range from the piezoelectric layer to an upper surface of the substrate in the region of the drive part is placed in a region of an outer peripheral portion of the movable part on the substrate,
a layer structure that is the same as in a range from the lower electrode layer to the upper surface of the substrate in the region of the drive part is placed in a region of a center portion of the movable part on the substrate, and
an upper surface of the lower electrode layer in the region of the center portion is exposed to outside to constitute a reflection surface.

2. The optical reflection element according to claim 1, wherein a layer structure from the upper electrode layer to an upper surface of the piezoelectric layer in the region of the drive part is further placed in the region of the outer peripheral portion of the movable part.

3. The optical reflection element according to claim 2, wherein the upper electrode layer in the region of the outer peripheral portion of the movable part is provided so as to be symmetrical about the rotation axis.

4. The optical reflection element according to claim 1, wherein an air retention portion for retaining air is formed by causing the piezoelectric layer placed in the outer peripheral portion of the movable part to protrude toward the center portion.

5. The optical reflection element according to claim 1, wherein the piezoelectric layer is composed of a single crystal structure.

6. A method for manufacturing an optical reflection element, comprising the steps of:
forming a lower electrode layer, a piezoelectric layer, and an upper electrode layer in this order from a substrate side;
removing the upper electrode layer such that the upper electrode layer is left at least in a range of a drive part;
removing the lower electrode layer and the piezoelectric layer such that the lower electrode layer and the piezoelectric layer are left at least in the range of the drive part and a range of a movable part;
removing the piezoelectric layer from the movable part such that the piezoelectric layer is left in an outer peripheral portion of the movable part to expose an upper surface of the lower electrode layer; and
removing the substrate in a range other than the optical reflection element.

7. The method for manufacturing the optical reflection element according to claim 6, wherein
in the step of removing the upper electrode layer, the upper electrode layer is also left in the outer peripheral portion of the movable part, and
in the step of removing the piezoelectric layer from the movable part, the piezoelectric layer is removed such that the upper electrode layer and the piezoelectric layer are left in the outer peripheral portion of the movable part.

8. The method for manufacturing the optical reflection element according to claim 6, wherein the step of removing the piezoelectric layer from the movable part includes a step of wet etching.
